(19) United States
(12) Patent Application Publication
(10) Pub. No.: US 2016/0073505 A1
(43) Pub. Date: Mar. 10, 2016

(54) MANUFACTURING METHOD OF MULTILAYER FLEXIBLE CIRCUIT STRUCTURE

(71) Applicant: Unimicron Technology Corp., Taoyuan (TW)

(72) Inventors: Cheng-Po Yu, Taoyuan County (TW); Kuo-Wei Li, Taipei City (TW)

(21) Appl. No.: 14/477,874

(22) Filed: Sep. 5, 2014

(51) Int. Cl. H05K 3/00; H05K 3/42; H05K 3/46

(52) U.S. Cl. CPC H05K 3/007; H05K 3/4652; H05K 3/4661; H05K 3/4673; H05K 3/421

(57) ABSTRACT

A manufacturing method of multilayer flexible circuit structure including the following steps is provided. Two first flexible substrates are correspondingly bonded on two sides of a release film, and two conductive materials are correspondingly formed on the two first flexible substrates. The two conductive materials are patterned to form two first inner-layer circuits. Two outer build-up structures are bonded on the two corresponding first flexible substrates. The release film is removed, so as to separate the two first flexible substrates. An outer-layer circuit is formed on each of the first flexible substrates and the corresponding outer build-up structure, wherein the outer-layer circuit is connected to the corresponding first inner-layer circuit, and each of the first flexible substrates, the corresponding first inner-layer circuit, the outer build-up structure and the outer-layer circuit correspondingly form a multilayer flexible circuit structure. Another manufacturing method of multilayer flexible circuit structure is also provided.

### BACKGROUND OF THE INVENTION

1. Field of the Invention

The invention relates to a manufacturing method of flexible circuit structure, and more particularly, relates a manufacturing method of multilayer flexible circuit structure.

2. Description of Related Art

In recent years, for expanding applications of a printed circuit board (PCB), many technologies have been proposed to manufacture the printed circuit board in a multilayer circuit structure. A manufacturing method of multilayer circuit structure includes composing a build-up structure by using a copper foil or other suitable conductive materials together with prepregs (pp) or other suitable dielectric materials, and repeatedly bonding the build-up structures to be laminated on a core layer to form the multilayer circuit structure, so as to increase internal layout spaces in the multilayer circuit structure. A conductive material on the build-up structure may form a conductive circuit according to a desired circuit layout, and blind holes or through holes in the build-up structure may be filled with additional conductive materials to conduct through each layer. Accordingly, a number of circuit layers in the multilayer circuit structure may be adjusted by requirements, and may be formed by aforesaid manufacturing method.

Similarly, a flexible printed circuit board (FPC) may also be formed in multilayer flexible circuit structure according to the aforesaid method, and a difference thereof is that a core layer of the multilayer flexible circuit structure is composed of flexible substrates. Specifically, the conductive material is disposed in a surface of the flexible substrate, and the conductive material may form the conductive circuit according to a desired circuit layout. Thereafter, as described above, the build-up structures are successively laminated and bonded on the core layer composed of the flexible substrate. The conductive material on the build-up structure may form another conductive circuit according to the desired circuit layout, and blind holes or through holes in the build-up structure may be filled with additional conductive materials to conduct through each of layers. However, since the flexible substrate is used as the core layer in the multilayer flexible circuit structure, during an initial processing of the flexible substrate (e.g., etching the conductive material on the flexible substrates to conductive circuits, or drilling holes on the build-up structure to form the blind holes or the through holes and electroplating the conductive material into the blind holes or the through holes for connecting each layer), the flexible substrate is prone to breakage and damage due to its thinner thickness or softer material during the initial processing. As a result, a process yield rate of the multilayer flexible circuit structure is relatively low, and thus a manufacturing cost thereof is increased accordingly.

### SUMMARY OF THE INVENTION

The invention provides manufacturing methods of the multilayer flexible circuit structure capable of improving the process yield rate and reducing the manufacturing cost.

The manufacturing method of multilayer flexible circuit structure of the invention includes the following steps. Two first flexible substrates are correspondingly bonded on two sides of a release film, and two conductive materials are correspondingly formed on the two first flexible substrates, so as to form a double-side flexible laminated structure, wherein each of the first flexible substrates is disposed between the corresponding conductive material and the release film. The two conductive materials are patterned to form two first inner-layer circuits. Two outer build-up structures are bonded on the two corresponding first flexible substrates, wherein each of the outer build-up structures includes a bonding layer and a second flexible substrate, and the bonding layer is disposed between the second flexible substrate and the corresponding first inner-layer circuit. The release film is removed, so as to separate the two first flexible substrates. An outer-layer circuit is formed on each of the first flexible substrates and the corresponding outer build-up structure, wherein the outer-layer circuit is connected to the corresponding first inner-layer circuit, and each of the first flexible substrates, the corresponding first inner-layer circuit, the outer build-up structure and the outer-layer circuit correspondingly form a multilayer flexible circuit structure.

The manufacturing method of multilayer flexible circuit structure includes the following steps. Two flexible laminated structures are correspondingly bonded on two sides of a release film to form a double-side flexible laminated structure, wherein each of the flexible laminated structures includes a first flexible substrate and a first conductive material and a second conductive material disposed in two opposite surfaces of the first flexible substrate, and each of the second conductive materials is disposed between the corresponding first flexible substrate and the release film. The two first conductive materials are patterned to form two first inner-layer circuits. Two outer build-up structures are bonded on the two corresponding flexible laminated structures, wherein each of the outer build-up structures includes a bonding layer and a second flexible substrate, and the bonding layer is disposed between the second flexible substrate and the corresponding first inner-layer circuit. The release film is removed, so as to separate the two flexible laminated structures. An outer-layer circuit is formed on each of the flexible laminated structures and the corresponding outer build-up structure, wherein the outer-layer circuit is connected to the corresponding first inner-layer circuit, and each of the flexible laminated structures, the corresponding first inner-layer circuit, the outer build-up structure and the outer-layer circuit correspondingly form a multilayer flexible circuit structure.

Based on above, the manufacturing method of multilayer flexible circuit structure provided by the invention includes bonding the two first flexible substrates at the two sides of the release film, and the first flexible substrate is disposed with the conductive materials. Accordingly, the initial processing may be performed on the two first flexible substrates and the two conductive materials disposed thereon at the same time. Further, since the two first flexible substrates are laminated together to increase the thickness, the occurrence of breakage and damage may be avoided during the initial processing of the first flexible substrate. After the initial processing is completed, the two first flexible substrates may be separated by removing the release film, and the subsequent processing may be proceeded to form two separated multilayer flexible circuit structures. Alternatively, the manufacturing method of multilayer flexible circuit structure provided by the invention includes bonding the two flexible laminated structures having double-side conductive materials on the two sides of the release film. Accordingly, the initial processing may be performed on the two flexible laminated structures at the same time. Further, since the two flexible laminated structures are laminated together to increase the thickness, the occurrence of breakage and damage may be avoided during the initial processing of the flexible laminated structures. After the initial processing is completed, the flexible laminated structures may be separated by removing the release film, and the subsequent processing may be proceeded to form two separated multilayer flexible circuit structures. Accordingly, the manufacturing methods of the multilayer flexible circuit structure provided by the invention are capable of improving the process yield rate and reducing the manufacturing cost.

To make the above features and advantages of the disclosure more comprehensible, several embodiments accompanied with drawings are described in detail as follows.

### BRIEF DESCRIPTION OF THE DRAWINGS

FIG. 1 is a flowchart illustrating steps of a manufacturing method of multilayer flexible circuit structure according to an embodiment of the invention.

FIG. 2A to FIG. 2G are schematic diagrams respectively illustrating each step of the manufacturing method of multilayer flexible circuit structure of FIG. 1.

FIG. 3 is a flowchart illustrating steps of a manufacturing method of multilayer flexible circuit structure according to another embodiment of the invention.

FIG. 4A to FIG. 4I are schematic diagrams respectively illustrating each step of the manufacturing method of multilayer flexible circuit structure of FIG. 3.

FIG. 5 is a flowchart illustrating steps of a manufacturing method of multilayer flexible circuit structure according to yet another embodiment of the invention.

FIG. 6A to FIG. 6H are schematic diagrams respectively illustrating each step of the manufacturing method of multilayer flexible circuit structure of FIG. 5.

FIG. 7 is a flowchart illustrating steps of a manufacturing method of multilayer flexible circuit structure according to still another embodiment of the invention.

FIG. 8A to FIG. 8I are schematic diagrams respectively illustrating each step of the manufacturing method of multilayer flexible circuit structure of FIG. 7.

### DESCRIPTION OF THE EMBODIMENTS

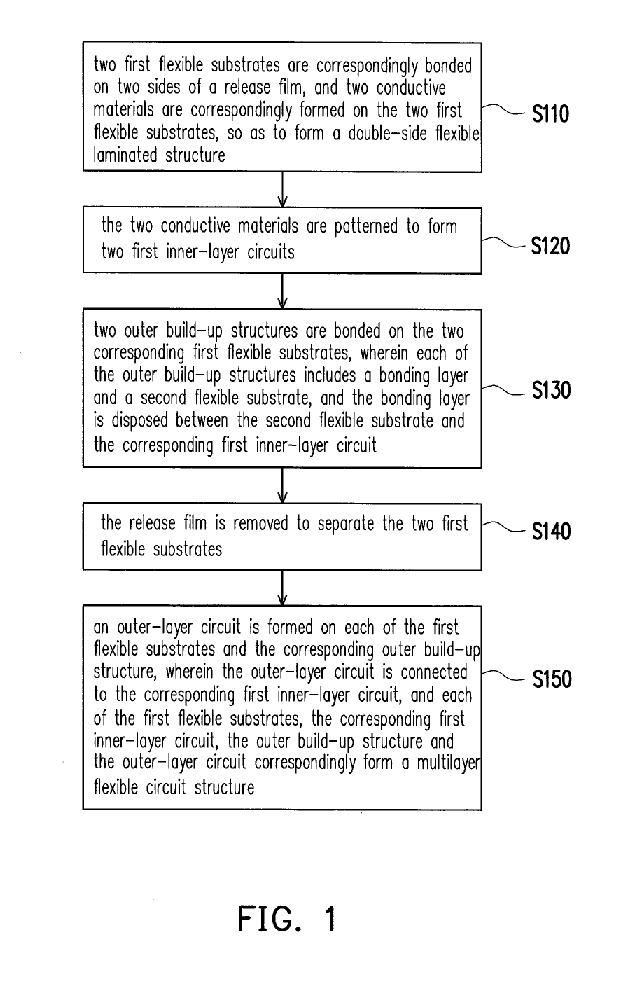

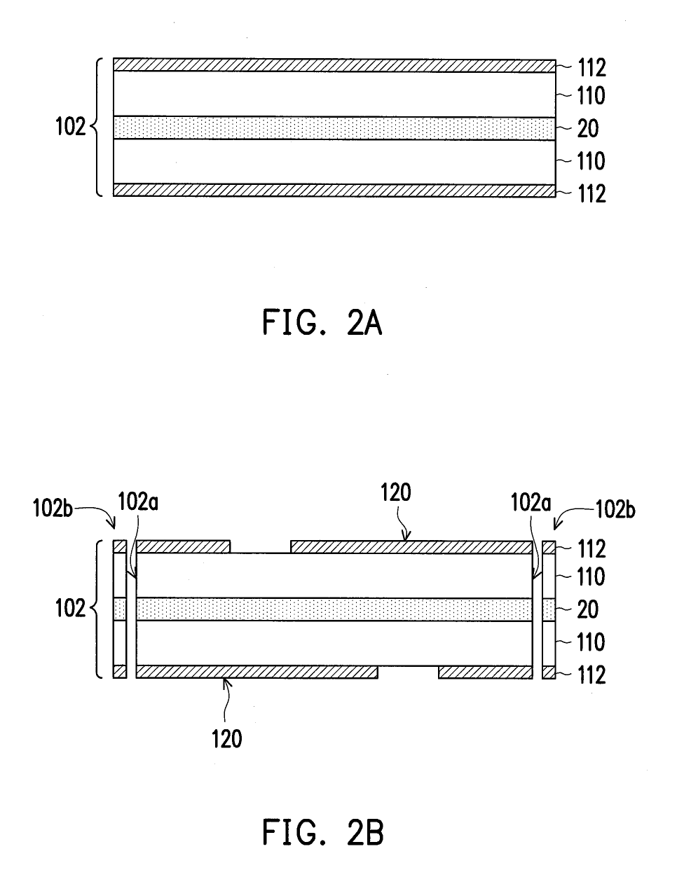

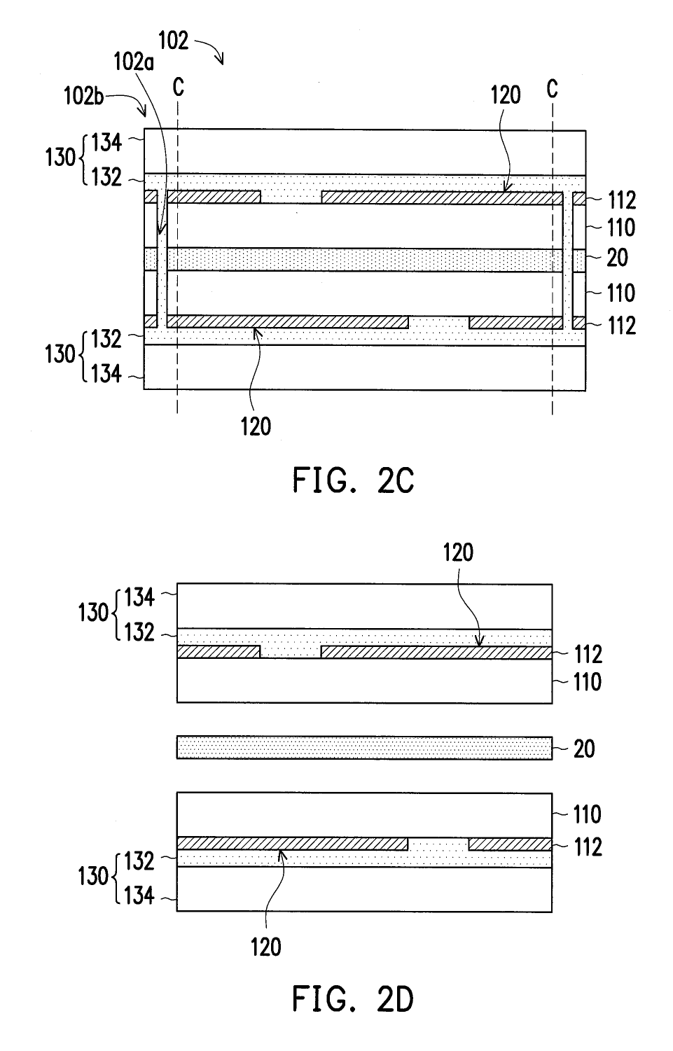

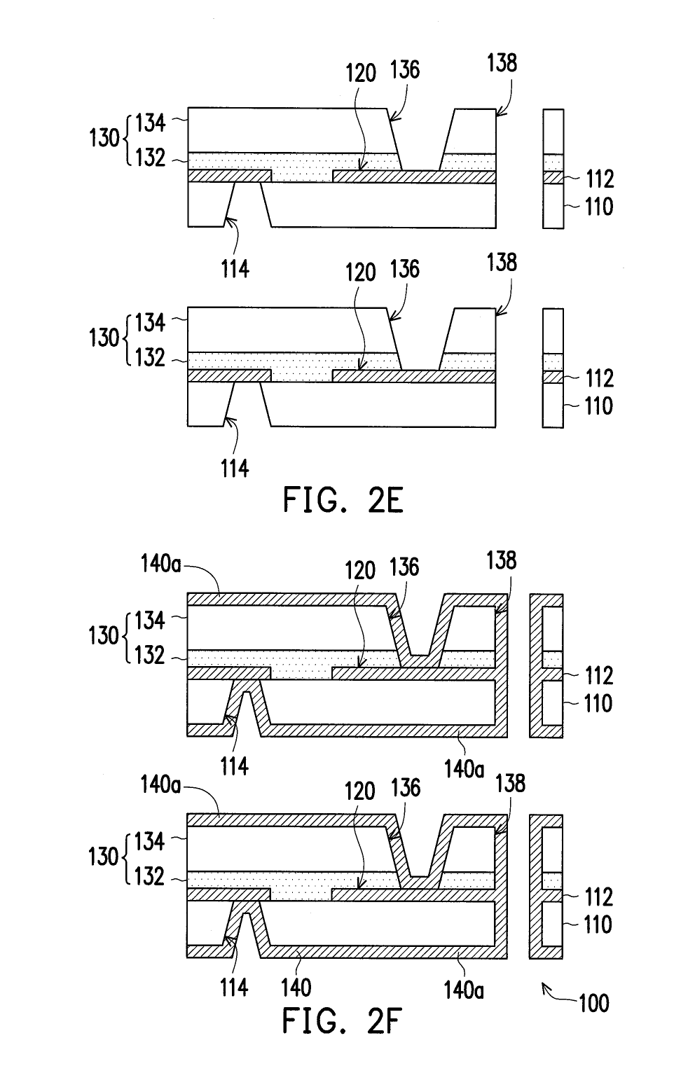

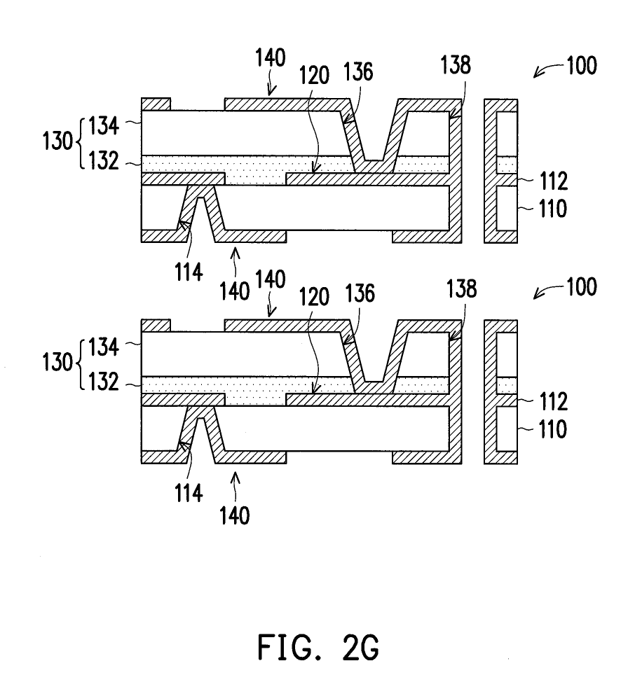

FIG. 1 is a flowchart illustrating steps of a manufacturing method of multilayer flexible circuit structure according to an embodiment of the invention. FIG. 2A to FIG. 2G are schematic diagrams respectively illustrating each step of the manufacturing method of multilayer flexible circuit structure of FIG. 1. Referring to FIG. 1, in the present embodiment, a manufacturing method of a multilayer flexible circuit structure 100 (illustrated in FIG. 2G) includes the following steps. The manufacturing method of the multilayer flexible circuit structure 100 of the present embodiment is described in texts by reference with FIG. 1 and FIG. 2A to FIG. 2G.

First, in step S110, two first flexible substrates 110 are correspondingly bonded on two sides of a release film 20, and two conductive materials 112 are correspondingly formed on the two first flexible substrates 110, so as to form a double-side flexible laminated structure 102. Each of the first flexible substrates 110 is disposed between the corresponding conductive material 112 and the release film 20. Specifically, referring to FIG. 1 and FIG. 2A, in the present embodiment, a material of each of the first flexible substrates 110 includes a flexible material, such as a thermosetting polyimide (PI), and a plurality of ceramic powders are uniformly distributed in each of the first flexible substrates 110. Each of the first flexible substrates 110 and the corresponding conductive material 112 may be formed by adopting a flexible copper clad laminate (FCCL), but the invention is not limited thereto. The step of forming the two conductive materials 112 on the two first flexible substrates 110 includes an electroplating process. However, a method of forming the conductive materials 112 may also include process such as sputtering, evaporation and so on, which is not particularly limited by the invention.

Herein, in case the conductive material 112 is formed by adopting the electroplating process, the conductive material 112 may be formed on a surface of the first flexible substrate 110 directly by electroplating process. Alternatively, before the conductive material 112 is formed on the surface of the first flexible substrate 110, a catalyst layer (or known as a seed layer, not illustrated) may be formed on the surface of the first flexible substrate 110 by electroless plating process or a sputtering process, so that the conductive material 112 may be formed on the first flexible substrate 110 with the catalyst layer. Specifically, before forming each of the conductive materials 112, an outer surface of each of the first flexible substrates 110 is micro-etched to remove the ceramic powders disposed in the outer surface of the first flexible substrates 110, so as to form a hyperactivity surface with a plurality of micro holes uniformly distributed. Accordingly, the micro holes which are uniformly distributed and having an aperture being approximately 200 nm may be left on the outer surface of each of the first flexible substrates 110. Thereafter, each of the first flexible substrates 110 is soaked in a solution having conductive ions, so as to form a conductive film (i.e., said catalyst layer) on the outer surface of each of the first flexible substrates 110, and this step refers to the electroless plating process as described above. A material of the catalyst layer may be a Pd—Ni layer or a Pd-Polymer layer, and an adhesive force thereof may be increased by the micro holes on the surface of the first flexible substrate 110. Thereafter, the conductive material 112 may be formed on the first flexible substrate 110 with the catalyst layer. However, the invention is not limited to aforesaid implementation, and a forming method of the conductive material 112 may be adjusted by requirements.

In addition, an order for manufacturing the conductive material 112 may be, forming the conductive materials 112 on the surfaces of the first flexible substrates 110 and then bonding the two first flexible substrates 110 formed with the conductive materials 112 together through the release film 20, or bonding the two first flexible substrates 110 together through the release film 20 and then forming the conductive materials 112 on the surfaces of the first flexible substrates 110, which is not particularly limited by the invention. Further, the release film 20 may be an entire adhesive layer or a partial colloid disposed between the two first flexible substrates 110. That is, a type of the release film 20 and a method of bonding the two first flexible substrates 110 through the release film 20 are not particularly limited by the invention. Since the first flexible substrate 110 of the present embodiment has the thinner thickness and the softer material, the two first flexible substrates 110 are bonded together through the release film 20 to increase the thickness. Thus, the two first flexible substrates 110 are not prone to breakage and damage. In addition, since the two first flexible substrates 110 are laminated together to form the double-side flexible laminated structure 102, the double-side flexible laminated structure 102 may be used as a whole to manufacture the two first flexible substrates 110 at the same time, so as to reduce the cost.

Next, in step S120, the two conductive materials 112 are patterned to form two first inner-layer circuits 120. Referring to FIG. 1 and FIG. 2B, in the present embodiment, since the surface of each of the first flexible substrates 110 without bonding on the release film 20 is disposed with the conductive material 112, the first inner-layer circuit 120 may be formed by patterning the conductive material 112. The step of patterning the two conductive materials 112 to form the two first inner-layer circuits 120 includes, for example, a photolithography process. The conductive material 112 may be etched to form conductive patterns and conductive circuits according to the desired circuit layout, so as to form the first inner-layer circuit 120. In addition, before the step of patterning the two conductive materials 112 to form the two first inner-layer circuits 120, an alignment target hole 102a may also be formed in advance on a periphery 102b of the double-side flexible laminated structure 102. The alignment target hole 102a penetrates the double-side flexible laminated structure 102. Although the alignment target holes 102a are illustrated at two opposite lateral sides of the double-side flexible laminated structure 102 in FIG. 2B, practically, take the double-side flexible laminated structure 102, the alignment target holes 102a may be disposed in corners or lateral sides of the double-side flexible laminated structure 102, and a quantity and a position of the alignment target holes 102 may be adjusted by requirements. Thereafter, in the step of patterning the two conductive materials 112 to form the two first inner-layer circuits 120, the alignment target hole 102a may be used for alignment to form the two first inner-layer circuits 120. However, whether to dispose the alignment target hole 102a or not is not particularly limited by the invention, which may be selected by requirements.

Next, in step S130, two outer build-up structures 130 are bonded on the two corresponding first flexible substrates 110, wherein each of the outer build-up structures 130 includes a bonding layer 132 and a second flexible substrate 134, and the bonding layer 132 is disposed between the second flexible substrate 134 and the corresponding first inner-layer circuit 120. Referring to FIG. 1 and FIG. 2C, in the present embodiment, the two outer build-up structures 130 are respectively bonded on the two corresponding first flexible substrates 110, wherein each of the outer build-up structures 130 includes the bonding layer 132 and the second flexible substrate 134, and the bonding layer 132 of each of the outer build-up structures 130 is facing the corresponding first flexible substrate 110 and bonded on the first inner-layer circuit 120. Each of the second flexible substrates 134 of the present embodiment is similar to the first flexible substrate 110, wherein a material of the second flexible substrates 134 includes a thermosetting polyimide (PI) or other flexible materials, and a plurality of ceramic powders are uniformly distributed in each of the second flexible substrates 134. In addition, the bonding layer 132 of the present embodiment is, for example, a colloid with adhesion. Accordingly, when the outer build-up structure 130 is bonded on the corresponding first flexible substrate 110, the bonding layer 132 may cover the first inner-layer circuit 120 and fill the alignment target hole 102a. However, materials of the bonding layer 132 and the second flexible substrate 134 are not particularly limited by the invention, which may be selected by requirements.

Next, in step S140, the release film 20 is removed, so as to separate the two first flexible substrates 110. Referring to FIG. 1 and FIG. 2D, in the present embodiment, the initial processing of each of the first flexible substrates 110 (e.g., forming the first inner-layer circuits 120) is substantially completed in the foregoing steps, and the thickness of each of the first flexible substrates 110 is increased after being correspondingly bonded with the outer build-up structure 130, such that a probability of breakage and damage to occur can be substantially lowered in the subsequent processing. Accordingly, this step removes the release film 20 between the two first flexible substrates 110, so that the two first flexible substrates 110 may be separated, and the subsequent processing may be performed respectively on the first flexible substrates 110 and the corresponding outer build-up structures 130. Further, in the present embodiment, before the step of removing the release film 20, a part of the periphery 102b of the double-side flexible laminated structure 102 may first be removed. For example, the part of the periphery 102b of the double-side flexible laminated structure 102 may be removed from a cutting line C depicted in FIG. 2C, wherein a removal range of the present embodiment covers the alignment target hole 102a, but the invention is not limited thereto. After the part of the periphery 102b of the double-side flexible laminated structure 102 is removed, a lateral side of the release film 20 may be exposed to facilitate actions for removing the release film 20. Alternatively, in the embodiment in which the partial colloid is served as the release film 20, if the cutting line C further falls on a part between the two first flexible substrates 110 where the release film 20 is not disposed, it also facilitates in directly separating the two first flexible substrates 110 and removing the release film 20.

Lastly, in step S150, an outer-layer circuit 140 is formed on each of the first flexible substrates 110 and the corresponding outer build-up structure 130, wherein the outer-layer circuit 140 is connected to the corresponding first inner-layer circuit 120, and each of the first flexible substrates 110, the corresponding first inner-layer circuit 120, the outer build-up structure 130 and the outer-layer circuit 140 correspondingly form the multilayer flexible circuit structure 100. Referring to FIG. 1 and FIG. 2E to FIG. 2G, in the present embodiment, the step of forming the outer-layer circuit 140 on each of the first flexible substrates 110 and the corresponding outer build-up structure 130 includes the following steps.

First, referring to FIG. 2E, a blind hole 114 and a blind hole 136 are respectively formed on each of the first flexible substrates 110 and the corresponding outer build-up structure 130, and a through hole 138 is formed on each of the first flexible substrates 110 and the corresponding outer build-up structure 130. In the present embodiment, the step of forming the blind holes 114 and 136 and the through hole 138 includes a laser drilling process and a mechanical drilling process, but the invention is not limited thereto. Herein, the blind holes 114 and 136 are respectively formed on the first flexible substrate 110 and the outer build-up structure 130 by using the laser drilling process, and the blind holes 114 and 136 are connected to the first inner-layer circuit 120 respectively; whereas the through hole 138 penetrates the first flexible substrate 110 and the outer build-up structure 130 by using the mechanical drilling process, and is connected to the first inner-layer circuit 120.

Next, referring to FIG. 2F, a conductive layer 140a is formed on each of the first flexible substrates 110 and the corresponding outer build-up structure 130, and each of the conductive layers 140a is connected to the corresponding first inner-layer circuit 120 through the corresponding blind holes 114 and 136 and the through hole 138. Specifically, in the present embodiment, the step of forming the conductive layer 140a includes an electroplating process, but the invention is not limited thereto. The conductive layer 140a is formed in the blind holes 114 and 136 and the through hole 138 by using the electroplating process, and covering on the surface of the first flexible substrate 110 and the surface of the second flexible substrate 134 of the outer build-up structure 130. Accordingly, the conductive layer 140a is connected to the corresponding first inner-layer circuit 120 through the corresponding blind holes 114 and 136 and the through hole 138. Similarly, before forming the conductive layer 140a by using the electroplating process, a catalyst layer (or known as a seed layer) may be formed on the surfaces of the first flexible substrate 110 and the second flexible substrate 134 by using an electroless plating process or a sputtering process, so that the conductive layer 140a may be formed on the first flexible substrate 110 and the second flexible substrate 134 with the catalyst layer as a medium and filled in the blind holes 114 and 136 and the through hole 138. Specifically, before forming each of the conductive layers 140a, the surfaces of the first flexible substrate 110 and the second flexible substrate 134 are first micro-etched to remove the ceramic powders disposed in the surfaces of each of the first flexible substrates 110 and each of the second flexible substrates 134, so that the hyperactivity surfaces having the micro holes being uniformly distributed may be formed on the surfaces of each of the first flexible substrates 110 and each of the second flexible substrates 134. Thereafter, each of the first flexible substrates 110 and each of the second flexible substrates 134 are soaked in a solution having conductive ions, so as to correspondingly form a conductive film (i.e., the catalyst layer) on the surfaces of each of the first flexible substrates 110 and each of the second flexible substrates 134. Thereafter, each of the conductive layers 140a may be formed on the first flexible substrate 110 and the second flexible substrate 134 with the catalyst layer as the medium and filled in the blind holes 114 and 136 and the through hole 138, but the invention is not limited to aforesaid implementation.

Lastly, referring to FIG. 2G, each of the conductive layers 140a is patterned to form the outer-layer circuit 140 on the corresponding first flexible substrate 110 and the second flexible substrate 130 of the outer build-up structure 130. Specifically, in the present embodiment, the step of forming the outer-layer circuit 140 includes a photolithography process, but the invention is not limited thereto. After the foregoing step is completed, the conductive layer 140a formed in the blind holes 114 and 136 and the through hole 138 and covering on the surfaces of the first flexible substrate 110 and outer build-up structure 130 is connected to the first inner-layer circuit 120. Accordingly, in this step, by using the photolithography process, the conductive layer 140a may be patterned according to the desired circuit layout, so that the conductive layer 140a may be etched to form conductive patterns and conductive circuits, so as to form the outer-layer circuit 140. The outer-layer circuit 140 is connected to the first inner-layer circuit 120 through the blind holes 114 and 136 and the through hole 138. Accordingly, each of the first flexible substrates 110, the corresponding first inner-layer circuit 120, the outer build-up structure 130 and the outer-layer circuit 140 may correspondingly form the multilayer flexible circuit structure 100.

In view of above, in the present embodiment, the first inner-layer circuit 120 disposed between the first flexible substrate 110 and the outer build-up structure 130 and the outer-layer circuit 140 disposed in the first flexible substrate 110 and the outer build-up structure 130 may be considered as three circuit layers formed on the multilayer flexible circuit structure 100 (the outer-layer circuit 140 may be considered as two circuit layers connected by the through hole 138). Accordingly, the multilayer flexible circuit structure 100 of the present embodiment may be considered as a three-layer flexible circuit structure. In addition, since the two first flexible substrates 110 are bonded through the release layer 20 first in the manufacturing process of the multilayer flexible circuit structure 100 in the present embodiment, during the initial processing (e,g., forming the first inner-layer circuit 120), the thicknesses of the two first flexible substrates 110 are increased to avoid occurrence of breakage and damage, and the two first flexible substrates 110 may be processed at the same time. After the initial processing of the first flexible substrate 110 is completed and the thickness thereof is increased through build-up of the outer build-up structure 130, the subsequent processing may be performed after separating the two first flexible substrates 110, so as to form the multilayer flexible circuit structure 100. Accordingly, the manufacturing method of the multilayer flexible circuit structure 100 of the present embodiment is capable of improving the process yield rate and reducing the manufacturing cost.

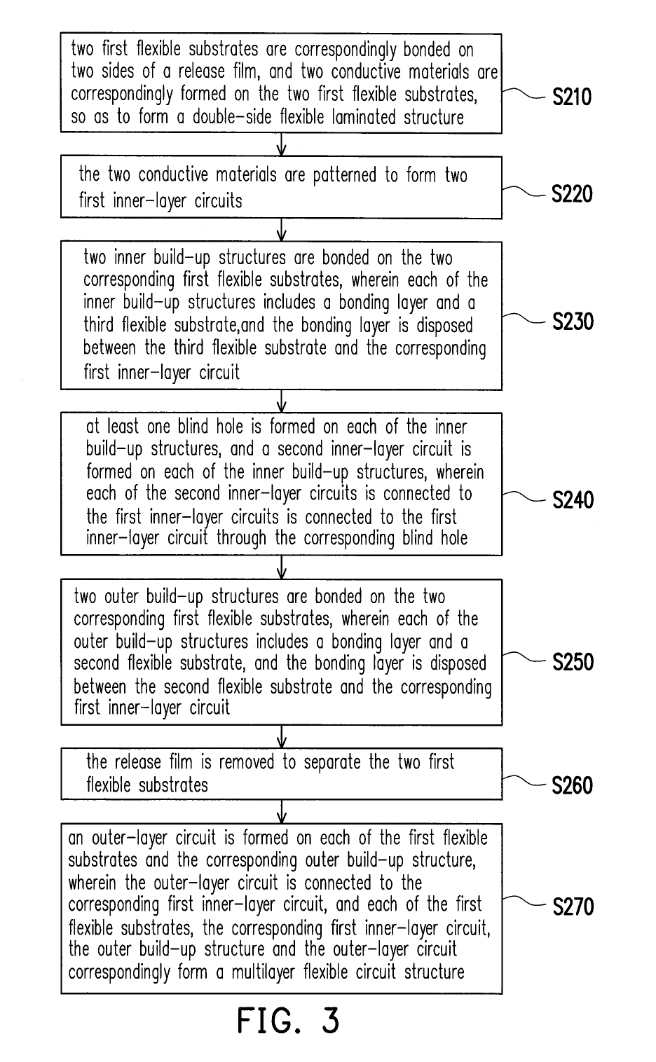

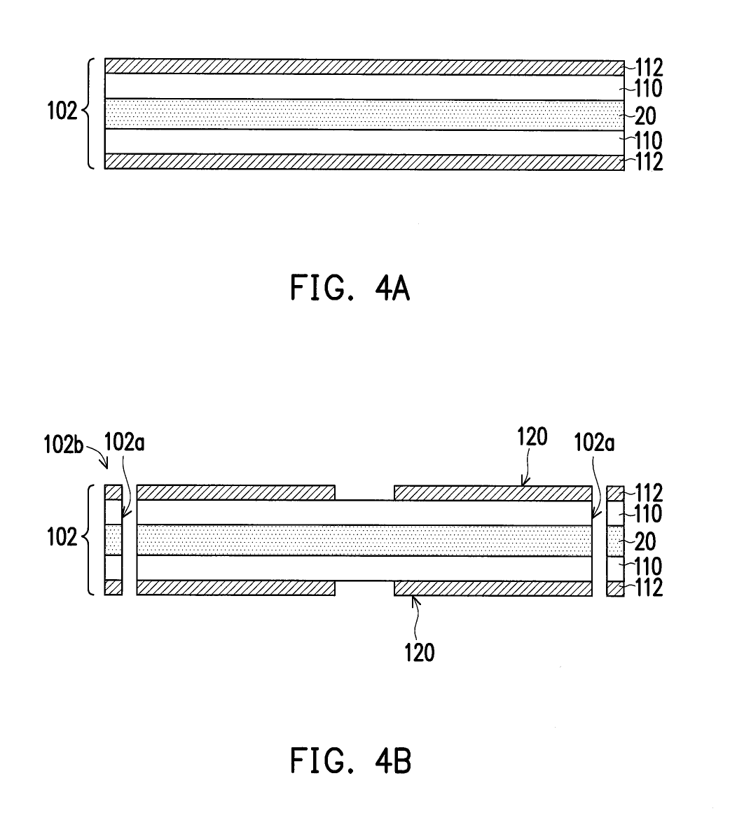

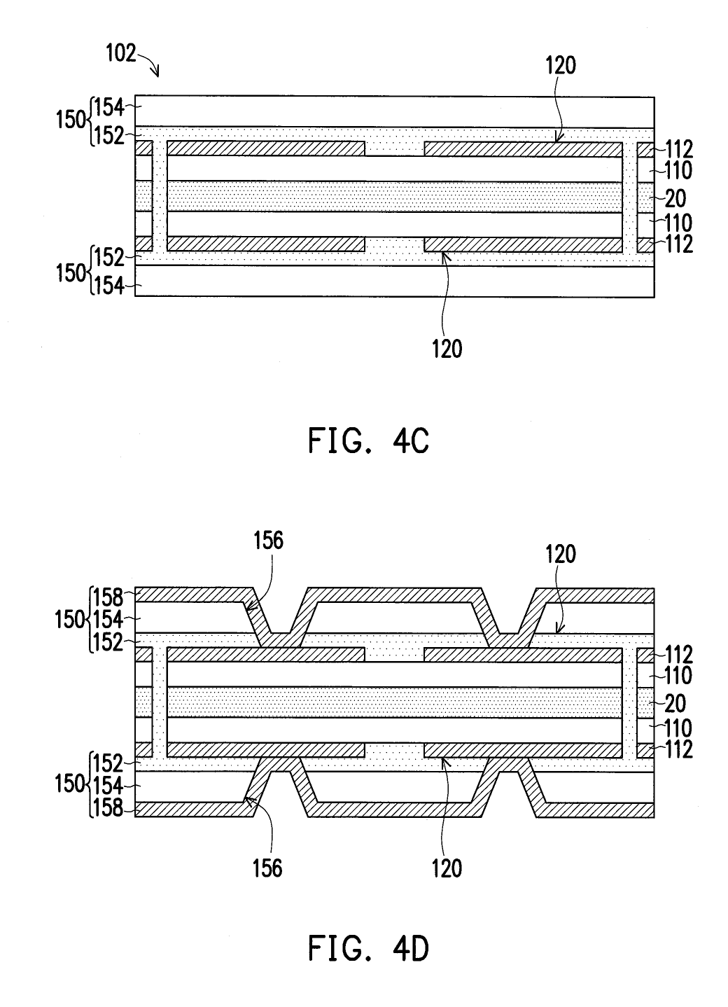

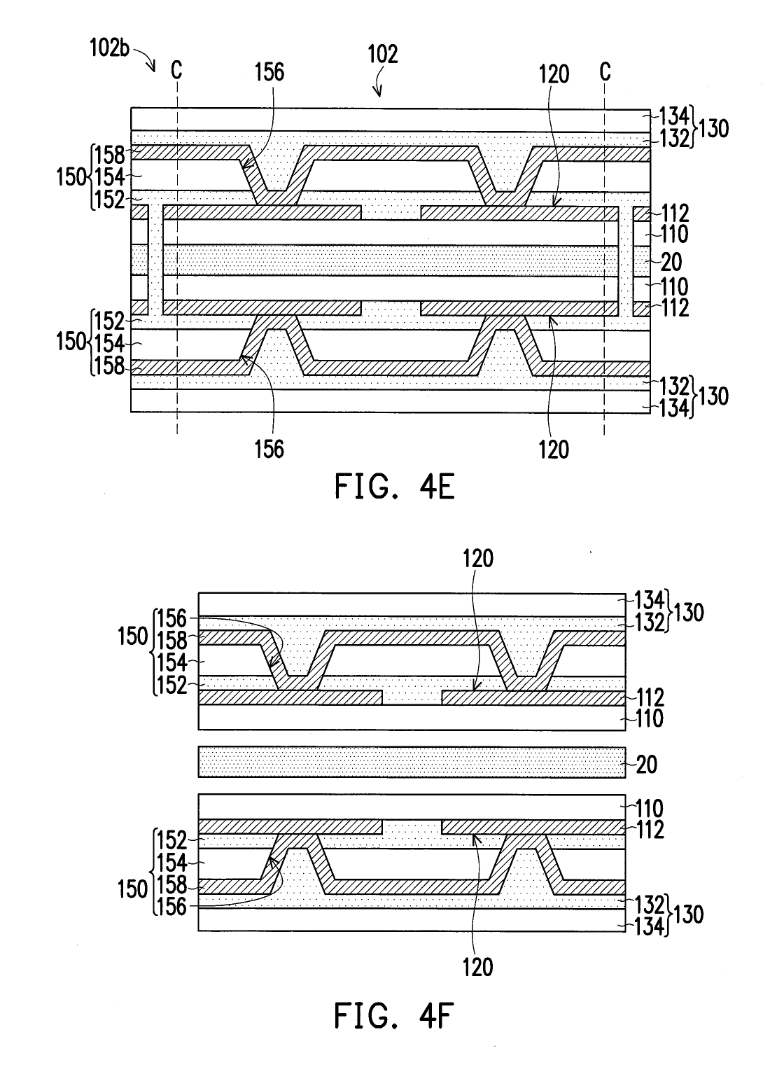

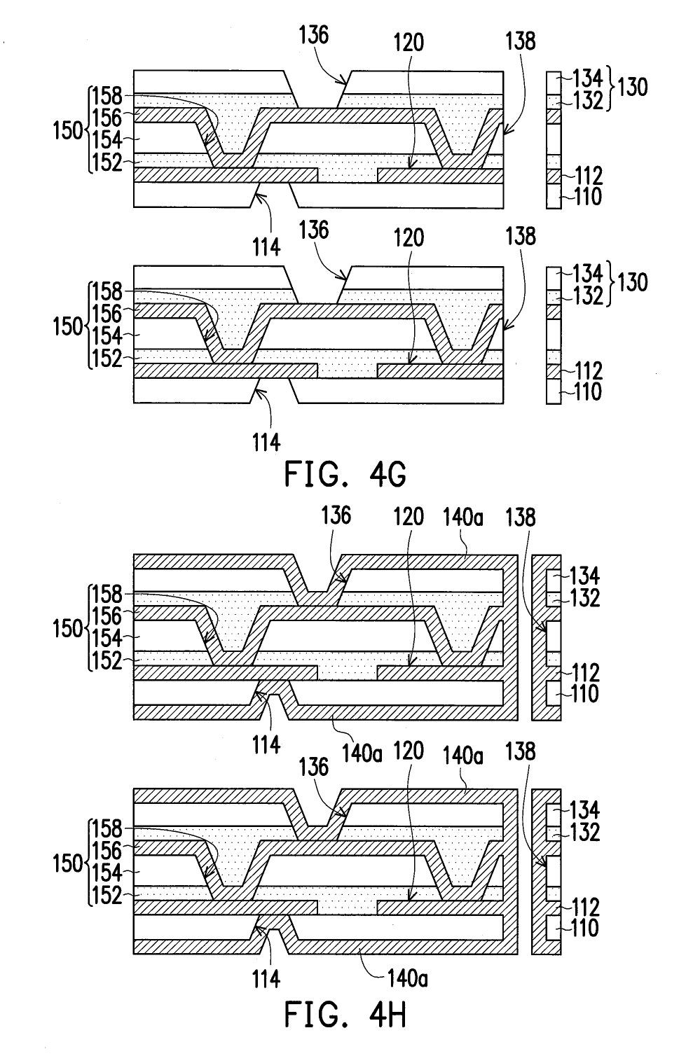

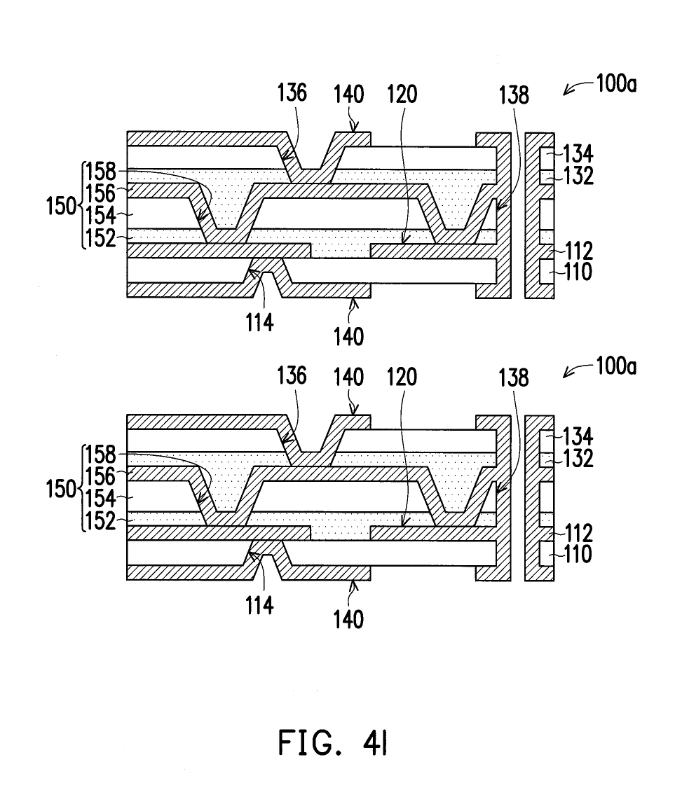

FIG. 3 is a flowchart illustrating steps of a manufacturing method of multilayer flexible circuit structure according to another embodiment of the invention. FIG. 4A to FIG. 4I are schematic diagrams respectively illustrating each step of the manufacturing method of multilayer flexible circuit structure of FIG. 3. Referring to FIG. 3, in the present embodiment, a manufacturing method of a multilayer flexible circuit structure 100a (illustrated in FIG. 4I) includes the following steps. The manufacturing method of the multilayer flexible circuit structure 100a of the present embodiment is described in texts by reference with FIG. 3 and FIG. 4A to FIG. 4I.

First, in step S210, two first flexible substrates 110 are correspondingly bonded on two sides of a release film 20, and two conductive materials 112 are correspondingly formed on the two first flexible substrates 110, so as to form a double-side flexible laminated structure 102. Each of the first flexible substrates 110 is disposed between the corresponding conductive material 112 and the release film 20. Next, in step S220, the two conductive materials 112 are patterned to form two first inner-layer circuits 120. Specifically, referring to FIG. 3, FIG. 4A and FIG. 4B, in the present embodiment, manufacturing processes of steps S210 and S220 may refer to aforesaid steps S110 and S120 (corresponding to FIG. 2A and FIG. 2B), and contents regarding the first flexible substrate 110 and the conductive material 112 may refer to the foregoing descriptions, which are not repeated hereinafter. Since the two first flexible substrates 110 of the present embodiment are laminated together through the release film 20 to form the double-side flexible laminated structure 102, the thickness of the first flexible substrate 110 may be increased accordingly to avoid breakage and damage in the subsequent initial processing, and the double-side flexible laminated structure 102 may be used as a whole to process the two first flexible substrates 110 at the same time, so as to further reduce the manufacturing cost.

Next, in step S230, two inner build-up structures 150 are bonded on the two corresponding first flexible substrates 110, wherein each of the inner build-up structures 150 includes a bonding layer 152 and a third flexible substrate 154, and the bonding layer 152 is disposed between the third flexible substrate 154 and the corresponding first inner-layer circuit 120. Referring to FIG. 3 and FIG. 4C, in the present embodiment, the two inner build-up structures 150 are respectively bonded on the two corresponding first flexible substrates 110, wherein each of the inner build-up structures 150 includes the bonding layer 152 and the third flexible substrate 154, and the bonding layer 152 of each of the inner build-up structures 150 is facing the corresponding first flexible substrate 110 and bonded on the first inner-layer circuit 120. Descriptions regarding the bonding layer 152 and the third flexible substrate 154 may refer to the above descriptions for the bonding layer 132, the first flexible substrate 110 and the second flexible substrate 134 (illustrated in FIG. 2C), which are not repeated hereinafter.

Next, in step S240, at least one blind hole 156 is formed on each of the inner build-up structures 150, and a second inner-layer circuit 158 is formed on each of the inner build-up structures 150, wherein each of the second inner-layer circuits 158 is connected to the first inner-layer circuit 120 through the corresponding blind hole 156. Referring to FIG. 3 and FIG. 4D, in the present embodiment, the step of forming the blind hole 156 includes, for example, a laser drilling process, and the step of forming the second inner-layer circuit 158 includes, for example, an electroplating process, but the invention is not limited thereto. After the step of bonding the two inner build-up structures 150 on the two corresponding first flexible substrates 110, the blind hole 156 is formed on the inner build-up structure 150 by using the laser drilling process, and the blind hole 156 is connected to the first inner-layer circuit 120. Thereafter, the second inner-layer circuit 158 is formed on a surface the third flexible substrate 154 of each of the inner-layer circuits 150 by using the electroplating process, and filled in the blind hole 156 connected to the first inner-layer circuit 120. Accordingly, each of the second inner-layer circuits 158 may be connected to the corresponding first inner-layer circuit 120 through the corresponding blind hole 156. Similarly, before forming the second inner-layer circuit 158 by using the electroplating process, a catalyst layer may also be formed by using the electroless plating process. A method of forming the catalyst layer may refer to the above, which includes: using the thermosetting polyimide having the ceramic powders to serve the third flexible substrate 154; and after forming the micro holes being uniformly distributed by micro-etching a surface of the third flexible substrate 154, soaking each of the third flexible substrates 154 in the solution having conductive ions to form the conductive film. Accordingly, the second inner-layer circuit 158 may be formed on the third flexible substrate 154 with the catalyst layer as a medium.

Next, in step S250, two outer build-up structures 130 are bonded on the two corresponding first flexible substrates 110, wherein each of the outer build-up structures 130 includes a bonding layer 132 and a second flexible substrate 134, and the bonding layer 132 is disposed between the second flexible substrate 134 and the corresponding first inner-layer circuit 120. Referring to FIG. 3 and FIG. 4E, in the present embodiment, the manufacturing process of step S250 is substantially similar to that of aforesaid step S130 (corresponding to FIG. 2C). A difference between the two is that, since the two inner build-up structures 150 are already bonded on the two corresponding first flexible substrates 110 before the step of bonding the two outer build-up structures 130 on the two corresponding first flexible substrates 110, the two outer build-up structures 130 of the present embodiment are practically bonded on the corresponding inner build-up structure 150. Therein, the bonding layer 132 of each of the outer build-up structures 130 is facing the corresponding inner build-up structure 150 and bonded on the second inner-layer circuit 158. In view of above, it can be known that, before the step of bonding the two outer build-up structures 130 on the two corresponding first flexible substrates 110, it is also possible that more than two of the inner build-up structures 150 are bonded on each of the first flexible substrates 110, and the blind hole 156 may be formed on the third flexible substrate 154 of each of the inner build-up structures 150 to connect the inner-layer circuit at each layer through the blind hole 156.

Next, in step S260, the release film 20 is removed, so as to separate the two first flexible substrates 110. Referring to FIG. 3 and FIG. 4F, in the present embodiment, the initial processing of each of the first flexible substrates 110 (e.g., forming the first inner-layer circuit 120 and the second inner-layer circuit 158) is substantially completed in the foregoing step, and the thickness of each of the first flexible substrates 110 is increased after being correspondingly bonded on the inner build-up structure 150 and the outer build-up structure 130, such that a probability of breakage and damage to occur can be substantially lowered in the subsequent processing. Accordingly, this step removes the release film 20 between the two first flexible substrates 110, so that the two first flexible substrates 110 may be separated, and the subsequent processing may be performed on the first flexible substrate 110 and the corresponding outer build-up structures 130. Further, before the step of removing the release film 20, a part of a periphery 102b of the double-side flexible laminated structure 102 may first be removed. For example, the part of the periphery 102b of the double-side flexible laminated structure 102 may be removed from a cutting line C depicted in FIG. 4E, so as to facilitate actions for removing the release film 20. Specific implementation regarding the above may refer to the description for aforesaid step S140.

Lastly, in step S270, an outer-layer circuit 140 is formed on each of the first flexible substrates 110 and the corresponding outer build-up structure 130, wherein the outer-layer circuit 140 is connected to the corresponding first inner-layer circuit 120 and the second inner-layer circuit 158, and each of the first flexible substrates 110, the corresponding first inner-layer circuit 120, the inner build-up structure 150, the second inner-layer circuit 158, the outer build-up structure 130 and the outer-layer circuit 140 correspondingly form the multilayer flexible circuit structure 100a. Referring to FIG. 3 and FIG. 4G to FIG. 4I, in the present embodiment, the step of forming the outer-layer circuit 140 on each of the first flexible substrates 110 and the corresponding outer build-up structure 130 may refer to aforesaid step S150. First, as shown in FIG. 4G, blind holes 114 and 136 are respectively formed on each of the first flexible substrates 110 and the corresponding outer build-up structure 130, and a through hole 138 is formed on each of the first flexible substrates 110 and the corresponding outer build-up structure 130. Next, as shown in FIG. 4H, a conductive layer 140a is formed on each of the first flexible substrates 110 and the corresponding outer build-up structure 130, and each of the conductive layers 140a is connected to the corresponding first inner-layer circuit 120 and the second inner-layer circuit 158 through the corresponding blind holes 114 and 136 and the through hole 138. Lastly, as shown in FIG. 4I, the outer-layer circuit 140 is formed on the corresponding first flexible substrate 110 and the outer build-up structure 130 through each of the conductive layers 140a.

Specifically, in the present embodiment, the blind holes 114 and 136 are respectively formed on the first flexible substrate 110 and the outer build-up structure 130 by using the laser drilling process, and connected to the first inner-layer circuit 120 and the second inner-layer circuit 158 respectively; whereas the through hole 138 penetrates the first flexible substrate 110 and the outer build-up structure 130 by using the mechanical drilling process, and is connected to the first inner-layer circuit 120 and the second inner-layer circuit 158. Nevertheless, the invention is not limited to aforesaid implementation. In addition, the conductive layer 140a is formed in the blind holes 114 and 136 and the through hole 138 by using the electroplating process, and covering on the surface of the first flexible substrate 110 and the surface of the second flexible substrate 134 of the outer build-up structure 130. Accordingly, each of the conductive layers 140a is connected to the corresponding first inner-layer circuit 120 and the second inner-layer circuit 158 through the corresponding blind holes 118 and 136 and the through hole 138. Further, the step of forming the outer-layer circuit 140 includes a photolithography process, but the invention is not limited thereto. In other words, after forming the conductive layer 140a, by using the photolithography process, the conductive layer 140a may be patterned according to the desired circuit layout, so that the conductive layer 140a may be etched to form conductive patterns and conductive circuits, so as to form the outer-layer circuit 140. The outer-layer circuit 140 is connected to the first inner-layer circuit 120 and the second inner-layer circuit 158 through the blind holes 114 and 136 and the through hole 138. Accordingly, each of the first flexible substrates 110, the corresponding first inner-layer circuit 120, the inner build-up structure 150, the second inner-layer circuit 158, the outer build-up structure 130 and the outer-layer circuit 140 may correspondingly form the multilayer flexible circuit structure 100a.

In view of above, it can be known that, the manufacturing method of the multilayer flexible circuit structure 100a of the present embodiment is similar to that of the previous embodiment, and includes the same effectiveness in improving the process yield rate and reducing the manufacturing cost. In addition, as compared to the previous embodiment, before the outer build-up structure 130 is bonded and the outer build-up structure 140 is formed in the present embodiment, the inner build-up structure 150 is bonded on the first flexible substrate 110 and another inner-layer circuit is formed. In other words, in the present embodiment, the first inner-layer circuit 120 disposed between the first flexible substrate 110 and the inner build-up structure 150, the second inner-layer circuit 158 disposed between the inner build-up structure 150 and the outer build-up structure 130, and the outer-layer circuit 140 disposed in the first flexible substrate 110 and the outer build-up structure 130 may be considered as four circuit layers formed on the multilayer flexible circuit structure 100a (the outer-layer circuit 140 may be considered as two circuit layers connected by the through hole 138). Accordingly, the multilayer flexible circuit structure 100a of the present embodiment may be considered as a four-layer flexible circuit structure. Therefore, the multilayer flexible circuit structure 100a of the present embodiment includes more layers in terms of the structure as compared to afore-said multilayer flexible circuit structure 100, so as to increase the inner layout spaces for the inner-layer circuits. Accordingly, in case the multilayer flexible circuit structure requires more circuit layers, more of the inner build-up structures 150 may be bonded according to afore-said steps before bonding the outer build-up structure 130, and the inner-layer circuits may be formed on each of the inner build-up structures 150, wherein the inner-layer circuits are connected to a previous inner-layer circuit through the blind hole. As a result, the multilayer flexible circuit structure 100a of the present embodiment is capable of increasing the layout space for the inner-layer circuits by requirements by adopting simple technical solutions.

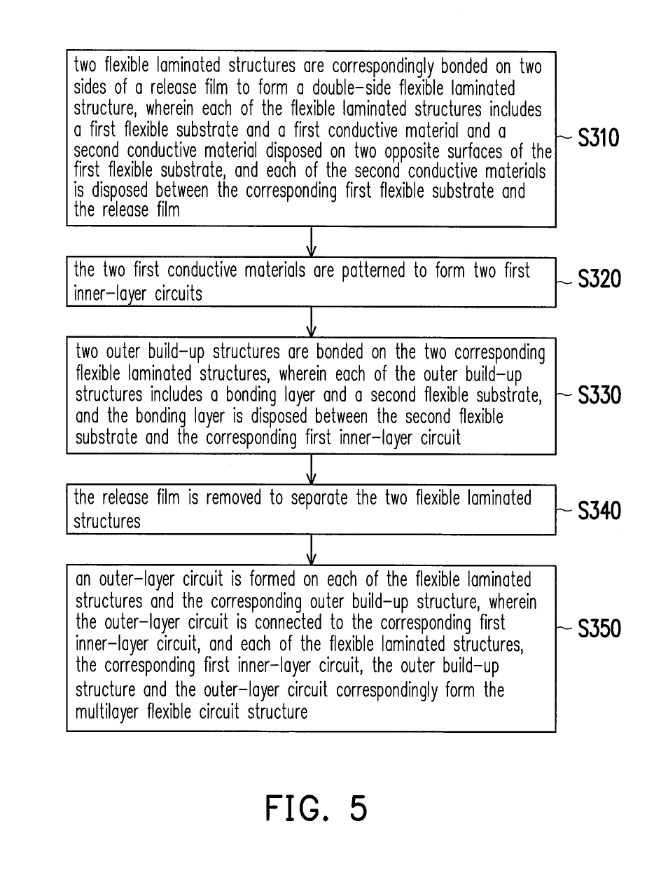

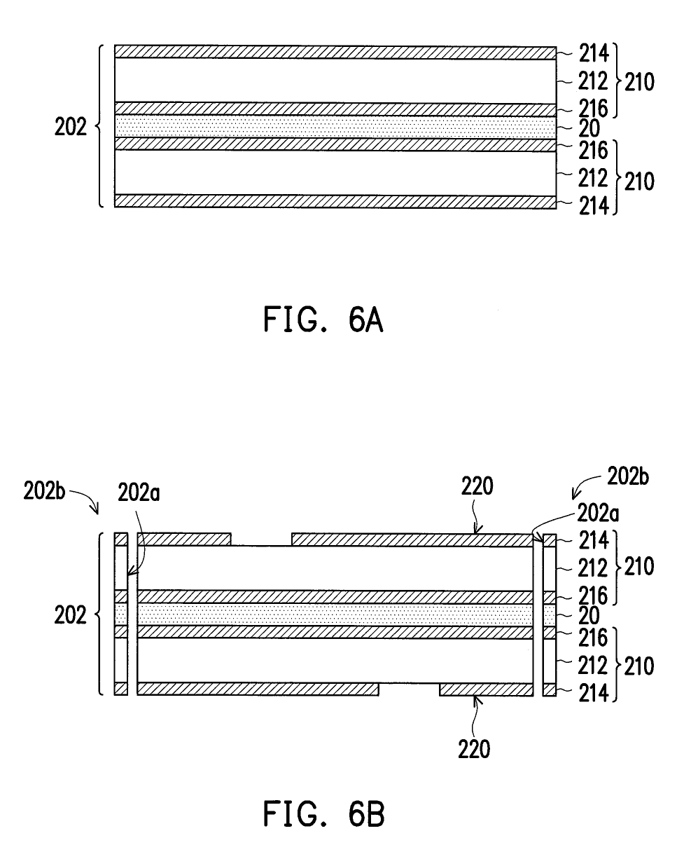

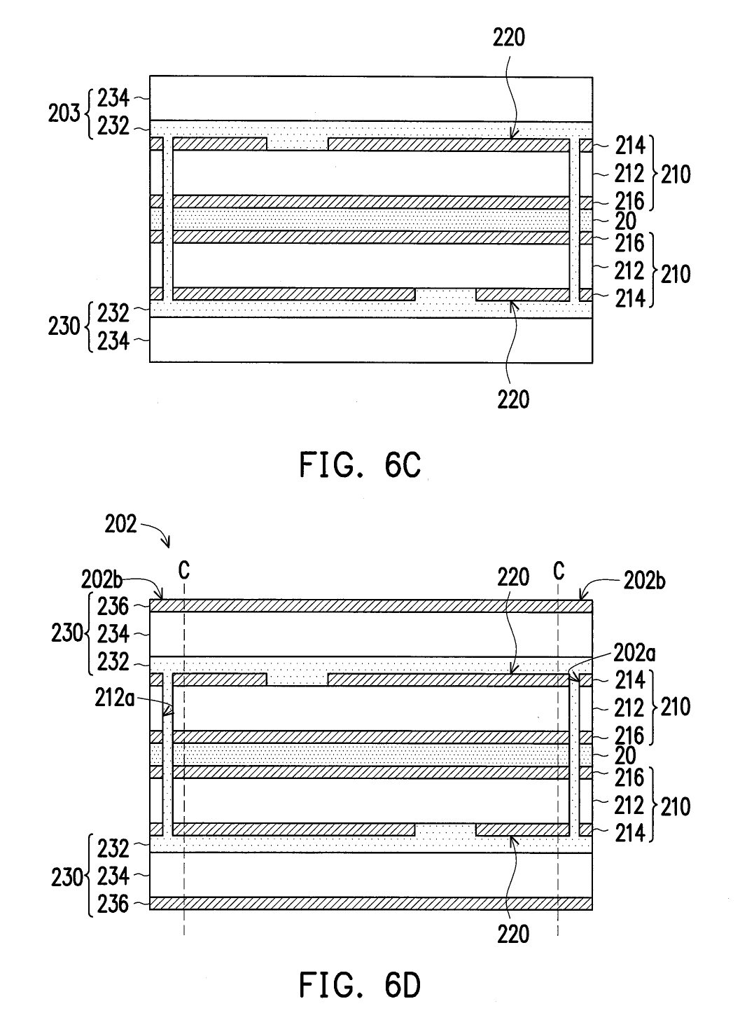

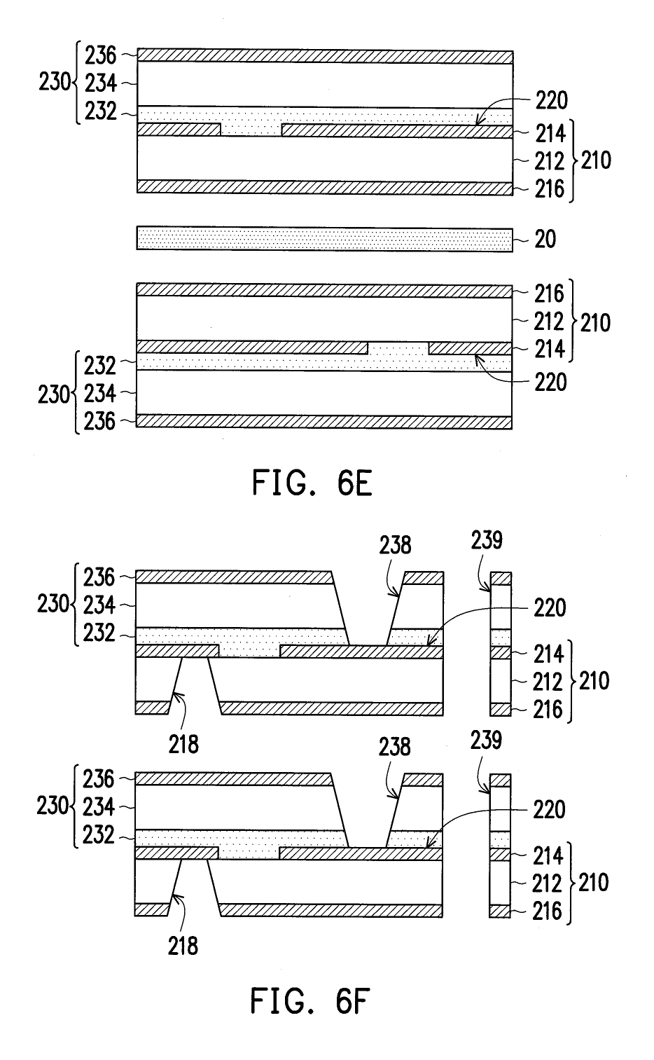

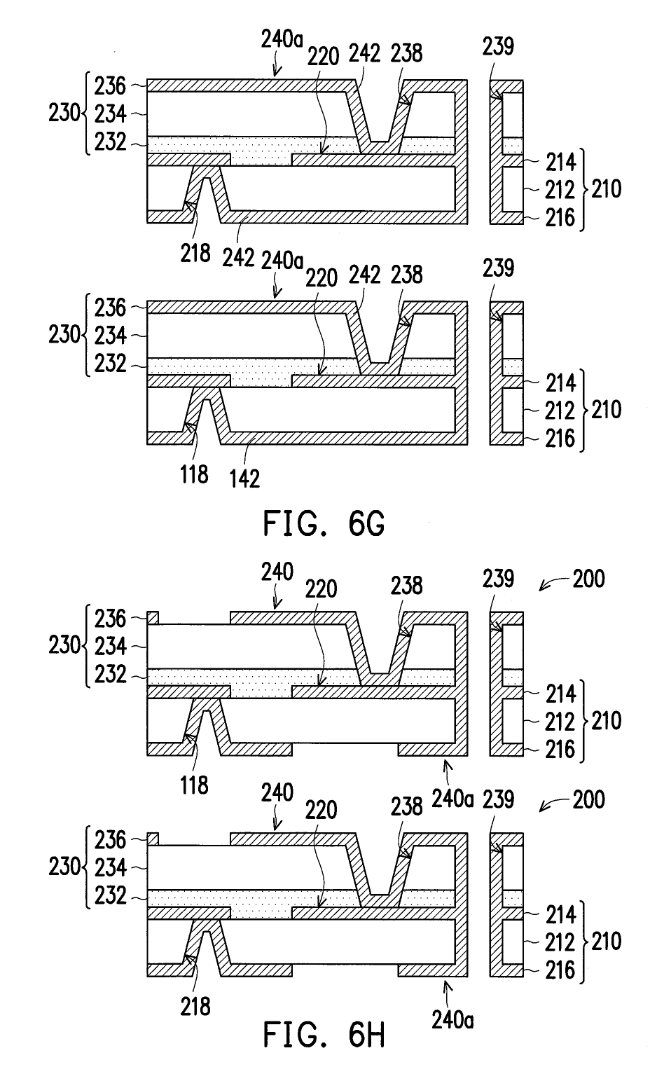

FIG. 5 is a flowchart illustrating steps of a manufacturing method of multilayer flexible circuit structure according to yet another embodiment of the invention. FIG. 6A to FIG. 6H are schematic diagrams respectively illustrating each step of the manufacturing method of multilayer flexible circuit structure of FIG. 5. Referring to FIG. 5, in the present embodiment, a manufacturing method of a multilayer flexible circuit structure 200 (illustrated in FIG. 6H) includes the following steps. The manufacturing method of the multilayer flexible circuit structure 200 of the present embodiment is described in texts by reference with FIG. 5 and FIG. 6A to FIG. 6H.

First, in step S310, two flexible laminated structures 210 are correspondingly bonded on two sides of a release film 20 to form a double-side flexible laminated structure 202, wherein each of the flexible laminated structures 210 includes a first flexible substrate 212 and a first conductive material 214 and a second conductive material 216 disposed in two opposite surfaces of the first flexible substrate 212, and each of the second conductive materials 216 is disposed between the corresponding first flexible substrate 212 and the release film 20. Specifically, referring to FIG. 5 and FIG. 6A, in the present embodiment, a material of each of the first flexible substrates 212 may be, for example, a thermosetting polyimide (PI) or other flexible materials, and a plurality of ceramic powders are uniformly distributed in each of the first flexible substrates 212. Materials of each of the first conductive materials 214 and each of the second conductive materials 216 may be, for example, a copper foil or other conductive materials. Accordingly, the flexible laminated structures 210 of the present embodiment may be formed by directly adopting a flexible copper clad laminate (FCCL), but the invention is not limited thereto. The two opposite surfaces of the first flexible material 212 of the flexible laminated structure 210 are both disposed with the first conductive material 214 and the second conductive material 216. The first conductive material 214 and the second conductive material 216 may be formed on the surfaces of the first flexible substrate 212 by using an electroplating process. After the first conductive material 214 and the second conductive material 216 are formed on the surfaces of the first flexible substrate 212 to constitute the flexible laminated structure 210, the two flexible laminated structures 210 are then bonded together through the release film 20. Nevertheless, a method of forming the first conductive material 214 and the second conductive material 216 may also include manufacturing methods such as sputtering, evaporation and so on, but the invention is not limited thereto.

Herein, in case the first conductive material 214 and the second conductive material 216 are formed by using the electroplating process, a catalyst layer (or known as a seed layer, not illustrated) may be formed on the surface of the first flexible substrate 212 by using an electroless plating process or a sputtering process, so that the first conductive material 214 and the second conductive material 216 may be formed on the first flexible substrate 212 with the catalyst layer as a medium. Specifically, before forming each of the first conductive materials 214 and each of the second conductive materials 216, the two opposite surfaces of each of the first flexible substrates 212 are micro-etched to form two hyperactivity surfaces having micro holes being uniformly distributed. In other words, by micro-etching the two opposite surfaces of each of the first flexible substrates 212, the ceramic powders disposed in the surfaces of each of the first flexible substrates 212 may be removed. Accordingly, the micro holes which are uniformly distributed may be left on the two surfaces of each of the first flexible substrates 212, and an aperture of the micro holes is approximately 200 nm. Thereafter, each of the first flexible substrates 212 is soaked in a solution having conductive ions, so as to correspondingly form two conductive films (i.e., said catalyst layer) on the two opposite surfaces of each of the first flexible substrates 212, and this step refers to the electroless plating process as described above. A material of the catalyst layer may be a Pd—Ni layer or a Pd-Polymer layer, and an adhesive force thereof may be increased by the micro holes on the surface of the first flexible substrate 212. Thereafter, the first conductive material 214 and the second conductive material 216 may be formed on the first flexible substrate 212 with the catalyst layer as the medium. However, the invention is not limited to aforesaid implementation, and a forming method of the first conductive material 214 and the second conductive material 216 may be adjusted by requirements.

Further, the release film 20 may be an entire adhesive layer or a partial colloid disposed between the two flexible laminated structures 210. That is, a type of the release film 20 and a method of bonding the two flexible laminated structures 210 through the release film 20 are not particularly limited by the invention. Since the flexible laminated structure 210 of the present embodiment has the thinner thickness and the softer material, the two flexible laminated structures 210 are bonded together through the release film 20 to increase the thickness. Accordingly, in the subsequent initial processing, the two flexible laminated structures 210 are not prone to breakage and damage due to the thinner thickness and the softer material. In addition, since the two flexible laminated structures 210 are laminated together to form the double-side flexible laminated structure 202, the double-side flexible laminated structure 202 may be used as a whole in the subsequent initial processing to process the two flexible laminated structures 210 at the same time, so as to reduce the manufacturing cost.

Next, in step S320, the two first conductive materials 214 are patterned to form two first inner-layer circuits 220. Referring to FIG. 5 and FIG. 6B, in the present embodiment, since the two surfaces of each of the flexible laminated structures 210 are disposed with the conductive materials (i.e., the first conductive material 214 and the second conductive material 216), the first inner-layer circuit 220 may be formed through the first conductive material 214 not bonded on the release film 20. In addition, before the step of patterning the two first conductive materials 214 to form the two first inner-layer circuits 220, an alignment target hole 202a may also be formed in advance on a periphery 202b of the double-side flexible laminated structure 202, and the alignment target hole 202a penetrates the double-side flexible laminated structure 202. Although the alignment target holes 202a are illustrated at two opposite lateral sides of the double-side flexible laminated structure 102 in FIG. 6B, practically, take the double-side flexible laminated structure 202 being a rectangular shape for example, the alignment target holes 202a may be disposed in corners or lateral sides of the double-side flexible laminated structure 202, and a quantity and a position of the alignment target holes 202 may be adjusted by requirements. Thereafter, in the step of patterning the two first conductive materials 214 to form the two first inner-layer circuits 220, the alignment target hole 202a may be used for alignment to form the two first inner-layer circuits 220. In addition, the step of patterning the two first conductive materials 214 to form the two first inner-layer circuits 220 includes, for example, a photolithography process. By using the photolithography process, the first conductive material 214 may be etched to form conductive patterns and conductive circuits according to the desired circuit layout, so as to form the first inner-layer circuit 220.

Next, in step S330, two outer build-up structures 230 are bonded on the two corresponding flexible laminated structures 210, wherein each of the outer build-up structures 230 includes a bonding layer 232 and a second flexible substrate 234, and the bonding layer 232 is disposed between the second flexible substrate 234 and the corresponding first inner-layer circuit 220. Referring to FIG. 5 and FIG. 6C, in the present embodiment, the two outer build-up structures 230 are respectively bonded on the two corresponding flexible laminated structures 210, wherein each of the outer build-up structures 230 includes the bonding layer 232 and the second flexible substrate 234, and the bonding layer 232 of each of the outer build-up structures 230 is facing the corresponding flexible laminated structure 210 and bonded on the first inner-layer circuit 220. Each of the second flexible substrates 234 of the present embodiment is similar to the first flexible substrate 212, and a material of the second flexible substrates 234 includes a thermosetting polyimide (PI) or other flexible materials, and a plurality of ceramic powders are uniformly distributed in each of the second flexible substrates 234. In addition, the bonding layer 232 of the present embodiment is, for example, a colloid with adhesion. Accordingly, when the outer build-up structure 230 is bonded on the corresponding flexible laminated structure 210, the bonding layer 232 may cover the first inner-layer circuit 220 and fill the alignment target hole 202a. However, materials of the bonding layer 232 and the second flexible substrate 234 are not particularly limited by the invention, which may be selected by requirements.

In addition, referring to FIG. 5 and FIG. 6D, in the present embodiment, the step of bonding the two outer build-up structures 230 on the two corresponding flexible laminated structures 210 further includes forming two third conductive materials 236 on the two corresponding second flexible substrates 234, and each of second flexible substrates 234 is disposed between the corresponding third conductive material 236 and the bonding layer 232. Specifically, the third conductive material 236 of the present embodiment is similar to the first conductive material 214 and the second conductive material 216, and a material thereof may adopt a copper foil or other conductive materials. The third conductive material 236 may be formed on a surface of the second flexible substrate 234 by using an electroplating process, but a manufacturing method thereof is not particularly limited by the invention. In addition, steps for manufacturing the third conductive material 236 may include forming the third conductive material 236 on the second flexible substrate 234 by using the electroplating process and then bonding the second flexible substrates 234 electroplated with the third conductive material 236 on the corresponding flexible laminated structure 210 through the bonding layer 232, or bonding the second flexible substrate 234 on the corresponding flexible laminated structure 210 through the bonding layer 232 and then forming the third conductive material 236 on the second flexible substrate 234 by using the electroplating process, which are not particularly limited by the invention. In addition, before the third conductive material 236 is formed by using the electroplating process, a catalyst layer (not illustrated) may be formed on the surface of the second flexible substrate 234 by using an electroless plating process or a sputtering process, so that the third conductive material 236 may be formed on the second flexible substrate 234 with the catalyst layer as a medium. For instance, before forming each of the third conductive materials 236, the surface of each of the second flexible substrates 234 is micro-etched to remove the ceramic powders disposed in the surface of each of the second flexible substrates 234, so as to form a hyperactivity surface having micro holes being uniformly distributed. Thereafter, each of the second flexible substrates 234 is soaked in a solution having conductive ions (i.e., said electroless plating process), so as to form a conductive film (i.e., the catalyst layer), and an adhesive force thereof may be increased by the micro holes on the surface of the second flexible substrate 234. Thereafter, the third conductive material 236 may be formed on the second flexible substrate 234 with the catalyst layer as the medium. Nevertheless, the invention is not limited to aforesaid implementation.

Next, in step S340, the release film 20 is removed, so as to separate the two flexible laminated structures 210. Referring to FIG. 5 and FIG. 6E, in the present embodiment, the initial processing of each of the flexible laminated structures 210 (e.g., forming the first inner-layer circuits 220) is substantially completed in the foregoing steps, and the thickness of each of the flexible laminated structures 210 is increased after being correspondingly bonded on the outer build-up structure 230, such that a probability of breakage and damage to occur can be substantially lowered in the subsequent processing. Accordingly, this step removes the release film 20 between the two flexible laminated structures 210, so that the two flexible laminated structures 210 may be separated, and the subsequent processing may be performed on the flexible laminated structure 210 and the corresponding outer build-up structures 230 respectively. Further, in the present embodiment, before the step of removing the release film 20, a part of the periphery 202b of the double-side flexible laminated structure 202 may first be removed. For example, the part of the periphery 202b of the double-side flexible laminated structure 202 may be removed from a cutting line C depicted in FIG. 6D, wherein a removal range of the present embodiment covers the alignment target hole 202a, but the invention is not limited thereto. After the part of the periphery 202b of the double-side flexible laminated structure 202 is removed, a lateral side of the release film 20 may be exposed to facilitate actions for removing the release film 20. Alternatively, in the embodiment in which the partial colloid is served as the release film 20, if the cutting line C further falls on a part between the two flexible laminated structures 210 where the release film 20 is not disposed, it also facilitates in directly separating the two flexible laminated structures 210 and removing the release film 20.

Lastly, in step S350, an outer-layer circuit 240 is formed on each of the flexible laminated structures 210 and the corresponding outer build-up structure 230, wherein the outer-layer circuit 240 is connected to the corresponding first inner-layer circuit 220, and each of the flexible laminated structures 210, the corresponding first inner-layer circuit 220, the outer build-up structure 230 and the outer-layer circuit 240 correspondingly form the multilayer flexible circuit structure 200. Referring to FIG. 5 and FIG. 6F to FIG. 6H, in the present embodiment, the step of forming the outer-layer circuit 240 on each of the flexible laminated structures 210 and the corresponding outer build-up structure 230 includes the following steps.

First, referring to FIG. 6F, a blind hole 218 and a blind hole 238 are respectively formed on each of the flexible laminated structures 210 and the corresponding outer build-up structure 230, and a through hole 239 is formed on each of the flexible laminated structures 210 and the corresponding outer build-up structure 230. In the present embodiment, the step of forming the blind holes 218 and 238 and the through hole 239 includes a mechanical drilling process and a laser drilling process, but the invention is not limited thereto. Herein, the blind holes 218 and 238 are respectively formed on the flexible laminated structure 210 and the outer build-up structure 230 by using the laser drilling process, and the blind holes 218 and 238 are connected to the first inner-layer circuit 220 respectively; whereas the through hole 239 penetrates the flexible laminated structure 210 and the outer build-up structure 230 by using the mechanical drilling process, and is connected to the first inner-layer circuit 220.

Next, referring to FIG. 6G, a conductive layer 240a is formed on each of the flexible laminated structures 210 and the corresponding outer build-up structure 230, and each of the conductive layers 240a is connected to the corresponding first inner-layer circuit 220 through the corresponding blind holes 218 and 238 and the through hole 239. Specifically, in the present embodiment, the step of forming the conductive layer 240a includes an electroplating process, but the invention is not limited thereto. Since the flexible laminated structure 210 of the present embodiment is disposed with the second conductive material 216 and the outer build-up structure 230 is disposed with the third conductive material 236, a conductive material 242 may be formed in the blind holes 218 and 238 and the through hole 239 by using the electroplating process and covering on the second conductive material 216 and the third conductive material 236, or may be formed only in the blind holes 218 and 238 and the through hole 239. Nevertheless, the invention is not limited to aforesaid implementation. The conductive material 242 disposed in the blind hole 218 is connected to the first inner-layer circuit 220 and the second conductive material 216; the conductive material 242 disposed in the blind hole 238 is connected to the first inner-layer circuit 220 and the third conductive material 236; and the conductive material 242 disposed in the through hole 239 is connected to the first inner-layer circuit 220, the second conductive material 216 and the third conductive material 236. Accordingly, the conductive layer 240a may be constituted in a manner of continuous layer by the conductive material 242 at least formed in the blind holes 218 and 238 and the through hole 239, the second conductive material 216 and the third conductive material 236, and the conductive layer 240a is connected to the corresponding first inner-layer circuit 220 through the corresponding blind holes 218 and 238 and the through hole 239.

Lastly, referring to FIG. 6H, the conductive layer 240a is patterned to form the outer-layer circuit 240. Specifically, in the present embodiment, the step of forming the outer-layer circuit 240 includes a photolithography process, but the invention is not limited thereto. After the foregoing step is completed, the conductive material 242 at least disposed in the blind holes 218 and 238 and the through hole 239 and the second conductive material 216 and the third conductive material 236 disposed in the flexible laminated structure 210 and the outer build-up structure 230 may form the conductive layer 240a connected to the first inner-layer circuit 220. Accordingly, in this step, by using the photolithography process, the second conductive pattern 216 and the third conductive pattern 236 that constitute the conductive layer 240a may be etched to form conductive patterns and conductive circuit according to the desired circuit layout, so as to form the outer-layer circuit 240, and the outer-layer circuit 240 is connected to the first inner-layer circuit 220 through the blind holes 218 and 238 and the through hole 239. Accordingly, each of the flexible laminated structures 210, the corresponding first inner-layer circuit 220, the outer build-up structure 230 and the outer-layer circuit 240 may correspondingly form the multilayer flexible circuit structure 200.

In view of above, since the two flexible laminated structures 210 are bonded through the release layer 20 first in the manufacturing process of the multilayer flexible circuit structure 200 in the present embodiment, during the initial processing (e,g., forming the first inner-layer circuit 220), the thicknesses of the two flexible laminated structures 210 are increased to avoid occurrence of breakage and damage, and the two flexible laminated structures 210 may be processed at the same time. After the initial processing of the flexible laminated structure 210 is completed and the thickness thereof is increased through build-up of the outer build-up structure 230, the subsequent processing may be performed after separating the two flexible laminated structures 210, so as to form the multilayer flexible circuit structure 200. Accordingly, the manufacturing method of the multilayer flexible circuit structure 200 of the present embodiment is capable of improving the process yield rate and reducing the manufacturing cost.

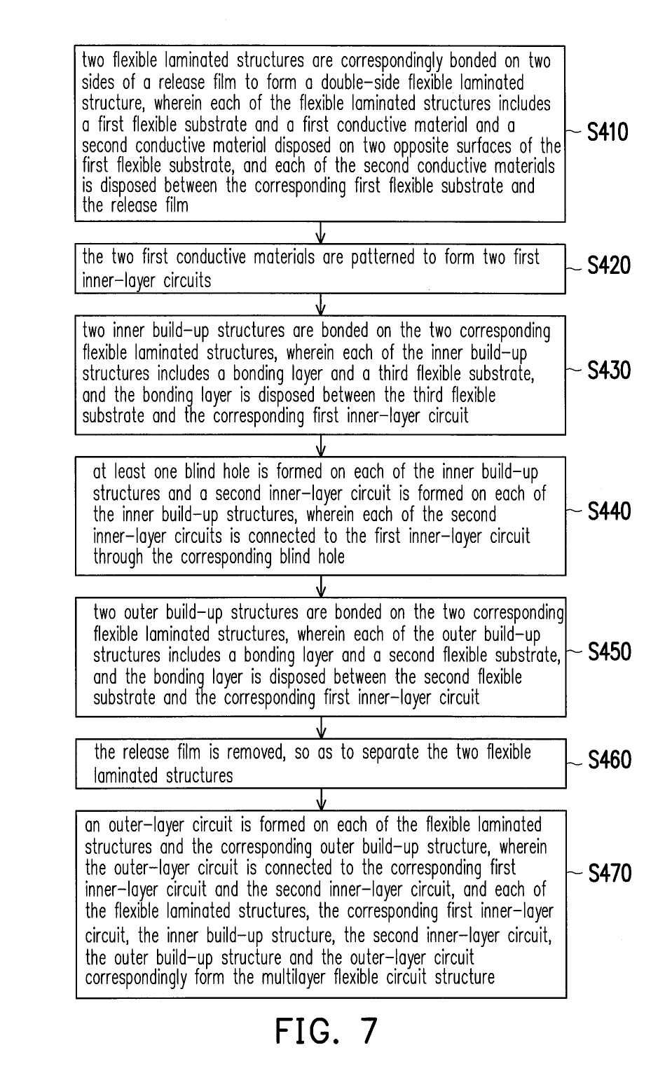

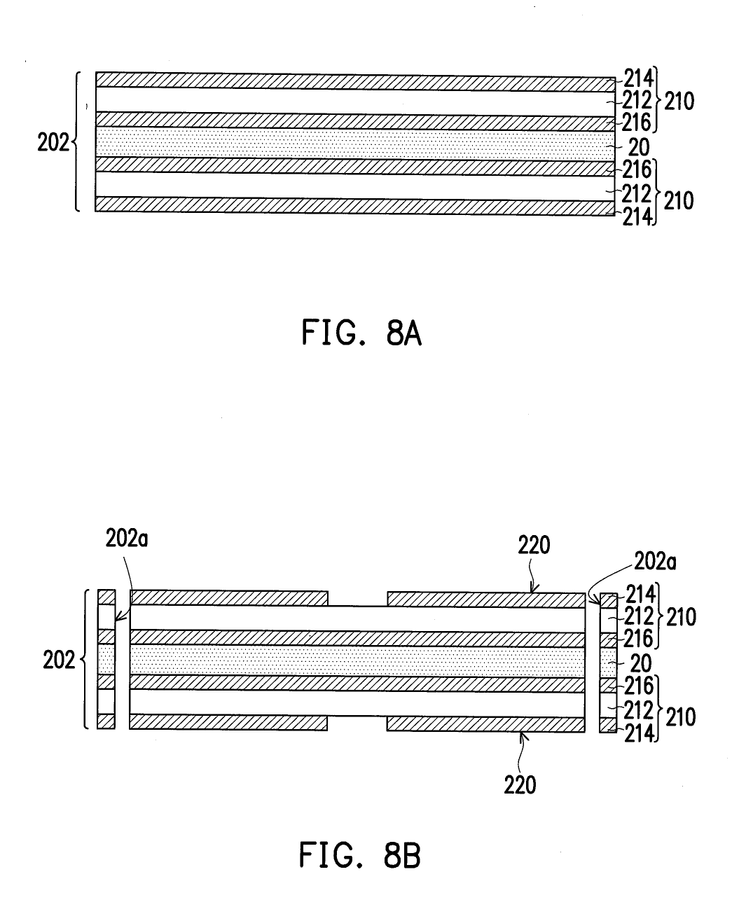

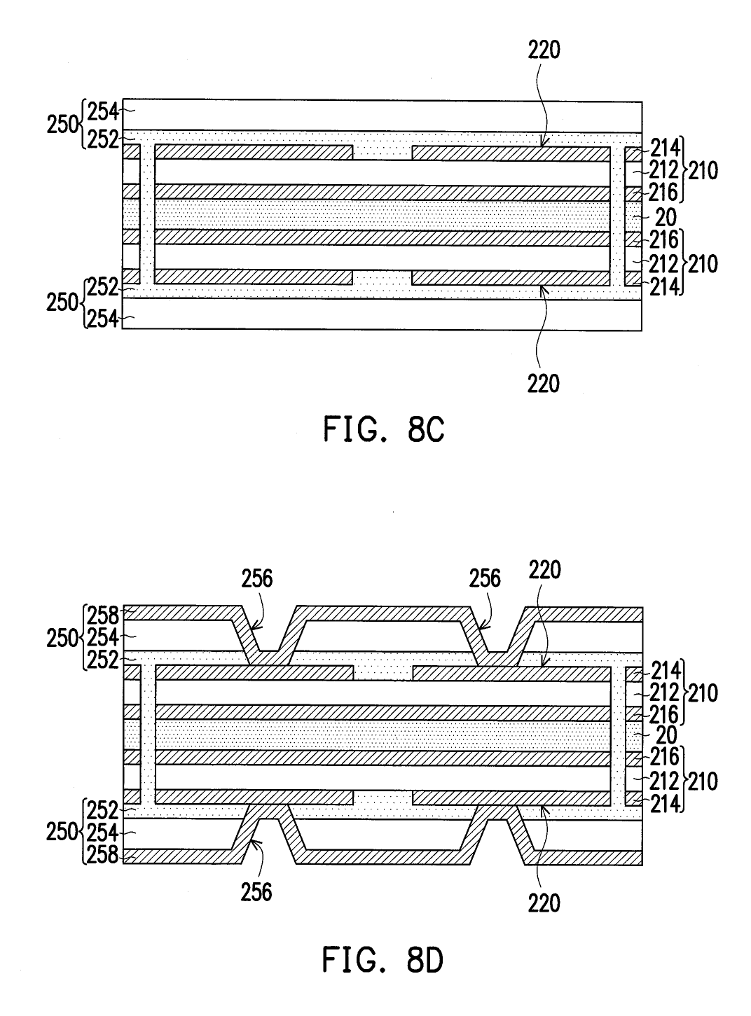

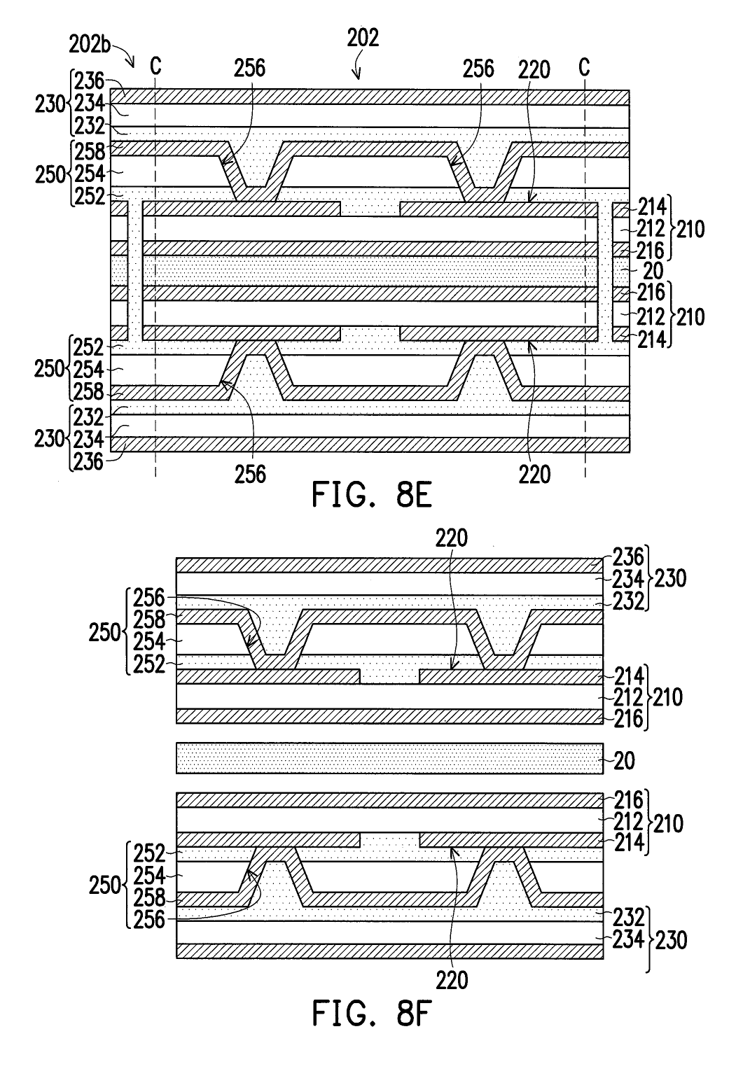

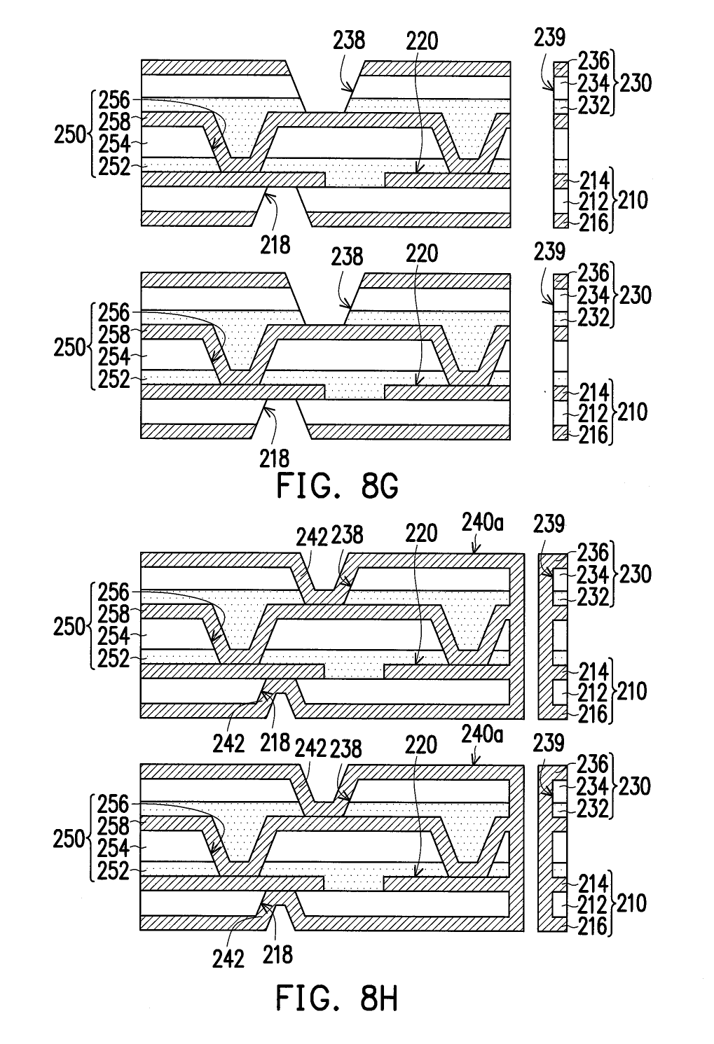

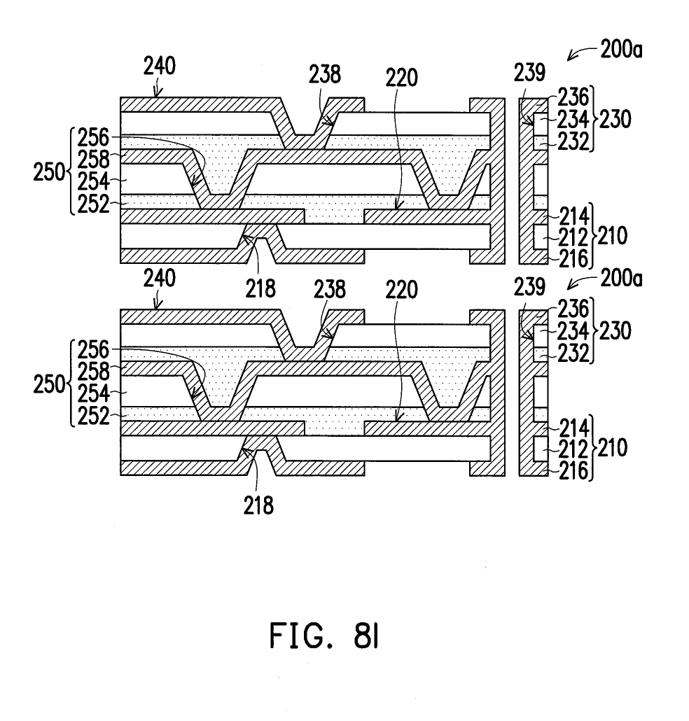

FIG. 7 is a flowchart illustrating steps of a manufacturing method of multilayer flexible circuit structure according to still another embodiment of the invention. FIG. 8A to FIG. 8I are schematic diagrams respectively illustrating each step of the manufacturing method of multilayer flexible circuit structure of FIG. 7. Referring to FIG. 7, in the present embodiment, a manufacturing method of a multilayer flexible circuit structure 200a (illustrated in FIG. 8I) includes the following steps. The manufacturing method of the multilayer flexible circuit structure 200a of the present embodiment is described in texts by reference with FIG. 7 and FIG. 8A to FIG. 8I.

First, in step S410, two flexible laminated structures 210 are correspondingly bonded on two sides of a release film 20 to form a double-side flexible laminated structure 202, wherein each of the flexible laminated structures 210 includes a first flexible substrate 212 and a first conductive material 214 and a second conductive material 216 disposed in two opposite surfaces of the first flexible substrate 212, and each of the second conductive materials 216 is disposed between the corresponding first flexible substrate 212 and the release film 20. Next, in step S420, the two first conductive materials 214 are patterned to form two first inner-layer circuits 220. Specifically, referring to FIG. 7, FIG. 8A and FIG. 8B, in the present embodiment, manufacturing processes of steps S410 and S420 may refer to aforesaid steps S310 and S320 (corresponding to FIG. 6A and FIG. 6B), and contents regarding the flexible laminated structure 210, the first flexible substrate 212, the first conductive material 214 and the second conductive material 216 may refer to the foregoing descriptions, which are not repeated hereinafter. Since the two flexible laminated structures 210 of the present embodiment are laminated together through the release film 20 to form the double-side flexible laminated structure 202, the thickness of the flexible laminated structure 210 may be increased accordingly to avoid breakage and damage in the subsequent initial processing, and the double-side flexible laminated structure 202 may be used as a whole to process the two flexible laminated structures 210 at the same time, so as to further reduce the manufacturing cost.

Next, in step S430, two inner build-up structures 250 are bonded on the two corresponding flexible laminated structures 210, wherein each of the inner build-up structures 250 includes a bonding layer 252 and a third flexible substrate 254, and the bonding layer 252 is disposed between the third flexible substrate 254 and the corresponding first inner-layer circuit 220. Referring to FIG. 7 and FIG. 8C, in the present embodiment, the two inner build-up structures 250 are respectively bonded on the two corresponding flexible laminated structures 210, wherein each of the inner build-up structures 250 includes the bonding layer 252 and the third flexible substrate 254, and the bonding layer 252 of each of the inner build-up structures 250 is facing the corresponding flexible laminated structure 210 and bonded on the first inner-layer circuit 220. Descriptions regarding the bonding layer 252 and the third flexible substrate 254 may refer to the above descriptions for the bonding layer 232, the first flexible substrate 212 and the second flexible substrate 234 (illustrated in FIG. 6C), which are not repeated hereinafter.

Next, in step S440, at least one blind hole 256 is formed on each of the inner build-up structures 250, and a second inner-layer circuit 258 is formed on each of the inner build-up structures 250, wherein each of the second inner-layer circuits 258 is connected to the first inner-layer circuit 220 through the corresponding blind hole 256. Referring to FIG. 7 and FIG. 8D, in the present embodiment, the step of forming the blind hole 256 includes, for example, a laser drilling process, and the step of forming the second inner-layer circuit 258 includes, for example, an electroplating process, but the invention is not limited thereto. After the step of bonding the two inner build-up structures 250 on the two corresponding flexible laminated structures 210, the blind hole 256 is formed on the inner build-up structure 250 by using the laser drilling process, and the blind hole 256 is connected to the first inner-layer circuit 220. Thereafter, the second inner-layer circuit 258 is formed on a surface the third flexible substrate 254 of each of the inner-layer circuits 250 by using the electroplating process, and filled in the blind hole 256 connected to the first inner-layer circuit 220. Accordingly, each of the second inner-layer circuits 258 may be connected to the corresponding first inner-layer circuit 220 through the corresponding blind hole 256. Similarly, before forming the second inner-layer circuit 258 by using the electroplating process, a catalyst layer may also be formed by using the electroless plating process. A method of forming the catalyst layer may refer to the above, which includes: using the thermosetting polyimide having the ceramic powders to serve the third flexible substrate 254; and after forming the micro holes being uniformly distributed by micro-etching a surface of the third flexible substrate 254, soaking each of the third flexible substrates 254 in the solution having conductive ions to form the conductive film. Accordingly, the second inner-layer circuit 258 may be formed on the third flexible substrate 254 with the catalyst layer as a medium.

Next, in step S450, two outer build-up structures 230 are bonded on the two corresponding flexible laminated structures 210, wherein each of the outer build-up structures 230 includes a bonding layer 232 and a second flexible substrate 234, and the bonding layer 232 is disposed between the second flexible substrate 234 and the corresponding first inner-layer circuit 220. Referring to FIG. 7 and FIG. 8E, in the present embodiment, the manufacturing process of step S450 is substantially similar to that of aforesaid step S330 (corresponding to FIG. 6C). A difference between the two is that, since the two inner build-up structures 250 of the present embodiment are already bonded on the two corresponding flexible laminated structures 210 before the step of bonding the two outer build-up structures 230 on the two corresponding flexible laminated structures 210, the two outer build-up structures 230 of the present embodiment are practically bonded on the corresponding inner build-up structure 250. Therein, the bonding layer 232 of each of the outer build-up structures 230 is facing the corresponding inner build-up structure 250 and bonded on the second inner-layer circuit 258. In addition, in the present embodiment, the step of bonding the two outer build-up structures 230 on the two corresponding flexible laminated structures 210 further includes a step of forming two third conductive materials 236 on the two corresponding second flexible substrates 234. Steps for manufacturing the third conductive material 236 may include forming the third conductive material 236 on the second flexible substrate 234 by using the electroplating process and then bonding the second flexible substrates 234 electroplated with the third conductive material 236 on the corresponding flexible laminated structure 210 through the bonding layer 232, or bonding the second flexible substrate 234 on the corresponding flexible laminated structure 210 through the bonding layer 232 and then forming the third conductive material 236 on the second flexible substrate 234 by using the electroplating process, which are not particularly limited by the invention. Structural composition regarding the outer build-up structure 230 (i.e., the bonding layer 232, the second flexible substrate 234 and the third conductive layer 236) may refer to the above descriptions, which is not repeated hereinafter.

Next, in step S460, the release film 20 is removed, so as to separate the two flexible laminated structures 210. Referring to FIG. 7 and FIG. 8F, in the present embodiment, the initial processing of each of the flexible laminated structures 210 (e.g., forming the first inner-layer circuits 220 and the second inner-layer circuits 258) is substantially completed in the foregoing steps, and the thickness of each of the flexible laminated structures 210 is increased after being correspondingly bonded on the outer build-up structure 230, such that a probability of breakage and damage to occur can be substantially lowered in the subsequent processing. Accordingly, this step removes the release film 20 between the two flexible laminated structures 210, so that the two flexible laminated structures 210 may be separated, and the subsequent processing may be performed on the flexible laminated structure 210 and the corresponding outer build-up structures 230 respectively. Further, before the step of removing the release film 20, a part of a periphery 202b of the double-side flexible laminated structure 202 may first be removed. For example, the part of the periphery 202b of the double-side flexible laminated structure 202 may be removed from a cutting line C depicted in FIG. 8E, so as to facilitate actions for removing the release film 20. Specific implementation regarding the above may refer to aforesaid description.

Lastly, in step S470, an outer-layer circuit 240 is formed on each of the flexible laminated structures 210 and the corresponding outer build-up structure 230, wherein the outer-layer circuit 240 is connected to the corresponding first inner-layer circuit 220 and the second inner-layer circuit 258, and each of the flexible laminated structures 210, the corresponding first inner-layer circuit 220, the inner build-up structure 250, the second inner-layer circuit 258, the outer build-up structure 230 and the outer-layer circuit 240 correspondingly form the multilayer flexible circuit structure 200a. Referring to FIG. 7 and FIG. 8G to FIG. 8I, in the present embodiment, the step of forming the outer-layer circuit 240 on each of the flexible laminated structures 210 and the corresponding outer build-up structure 230 includes the following steps.

First, referring to FIG. 8G, a blind hole 218 and a blind hole 238 are respectively formed on each of the flexible laminated structures 210 and the corresponding outer build-up structure 230, and a through hole 239 is formed on each of the flexible laminated structures 210 and the corresponding outer build-up structure 230. In the present embodiment, the step of forming the blind holes 218 and 238 and the through hole 239 includes a laser drilling process and a mechanical drilling process, but the invention is not limited thereto. Herein, the blind holes 218 and 238 are respectively formed on the flexible laminated structure 210 and the outer build-up structure 230 by using the laser drilling process, and the blind holes 218 and 238 are connected to the first inner-layer circuit 220 and the second inner-layer circuit 258 respectively; whereas the through hole 239 penetrates the flexible laminated structure 210 and the outer build-up structure 230 by using the mechanical drilling process, and is connected to the first inner-layer circuit 220 and the second inner-layer circuit 258.

Next, referring to FIG. 8H, a conductive layer 240a is formed on each of the flexible laminated structures 210 and the corresponding outer build-up structure 230, and each of the conductive layers 240a is connected to the corresponding first inner-layer circuit 220 and the second inner-layer circuit 258 through the corresponding blind holes 218 and 238 and the through hole 239. Specifically, in the present embodiment, the step of forming the conductive layer 240a includes an electroplating process, but the invention is not limited thereto. The conductive material 242 may be formed in the blind holes 218 and 238 and the through hole 239 by using the electroplating process and covering on the second conductive material 216 and the third conductive material 236, or may be formed only in the blind holes 218 and 238 and the through hole 239. Nevertheless, the invention is not limited to aforesaid implementation. The conductive material 242 disposed in the blind hole 218 is connected to the second inner-layer circuit 258 and the second conductive material 216; the conductive material 242 disposed in the blind hole 238 is connected to the second inner-layer circuit 258 and the third conductive material 236; and the conductive material 242 disposed in the through hole 239 is connected to the first inner-layer circuit 220, the second inner-layer circuit 258, the second conductive material 216 and the third conductive material 236. Accordingly, the conductive layer 240a may be constituted in a manner of continuous layer by the conductive material 242 at least formed in the blind holes 218 and 238 and the through hole 239, the second conductive material 216 and the third conductive material 236, and the conductive layer 240a is connected to the corresponding first inner-layer circuit 220 and the second inner-layer circuit 258 through the corresponding blind holes 218 and 238 and the through hole 239.

Lastly, referring to FIG. 8I, each of the conductive layers 240a is patterned to form the outer-layer circuit 240. Specifically, in the present embodiment, the step of forming the outer-layer circuit 240 includes a photolithography process, but the invention is not limited thereto. After the foregoing step is completed, the conductive material 242 at least disposed in the blind holes 218 and 238 and the through hole 239 and the second conductive material 216 and the third conductive material 236 disposed in the flexible laminated structure 210 and the outer build-up structure 230 may form the conductive layer 240a connected to the first inner-layer circuit 220 and the second inner-layer circuit 258. Accordingly, in this step, by using the photolithography process, the second conductive pattern 216 and the third conductive pattern 236 that constitute the conductive layer 240a may be etched to form conductive patterns and conductive circuit according to the desired circuit layout, so as to form the outer-layer circuit 240, and the outer-layer circuit 240 is connected to the first inner-layer circuit 220 and the second inner-layer circuit 258 through the blind holes 218 and 238 and the through hole 239. Accordingly, each of the flexible laminated structures 210, the corresponding first inner-layer circuit 220, the inner build-up structure 250, the second inner-layer circuit 258, the outer build-up structure 230 and the outer-layer circuit 240 may correspondingly form the multilayer flexible circuit structure 200a.

In view of above, it can be known that, the manufacturing method of the multilayer flexible circuit structure 200a of the present embodiment is similar to that of the previous embodiment, and includes the same effectiveness in improving the process yield rate and reducing the manufacturing cost. In addition, as compared to the previous embodiment, before the outer build-up structure 230 is bonded and the outer build-up structure 240 is formed in the present embodiment, the inner build-up structure 250 is bonded on the flexible laminated structure 210 and another inner-layer circuit is formed. Therefore, the multilayer flexible circuit structure 200a of the present embodiment includes more layers in terms of the structure as compared to afore-said multilayer flexible circuit structure 200, so as to increase the inner layout spaces for the inner-layer circuits. Accordingly, in case the multilayer flexible circuit structure requires more circuit layers, more of the inner build-up structures 250 may be bonded according to afore-said steps before bonding the outer build-up structure 230, and the inner-layer circuits may be formed on each of the inner build-up structures 250, wherein the inner-layer circuit is connected to a previous inner-layer circuit through the blind holes. As a result, the multilayer flexible circuit structure 200a of the present embodiment is capable of increasing the inner layout spaces for the inner-layer circuits by requirements by adopting simple technical solutions.

In summary, the manufacturing method of multilayer flexible circuit structure provided by the invention includes bonding the two first flexible substrates at the two sides of the release film, and the two first flexible substrates are correspondingly disposed with the two conductive materials. Accordingly, the initial processing may be performed on the two first flexible substrates and the two conductive materials disposed thereon at the same time. Further, since the two first flexible substrates are laminated together to increase the thickness, the occurrence of breakage and damage may be avoided during the initial processing of the first flexible substrate. After the initial processing is completed, the two first flexible substrates may be separated by removing the release film, and the subsequent processing may be proceeded to form two separated multilayer flexible circuit structures. Alternatively, the manufacturing method of multilayer flexible circuit structure provided by the invention includes bonding the two flexible laminated structures having double-side conductive materials on the two sides of the release film. Accordingly, the initial processing may be performed on the two flexible laminated structures at the same time. Further, since the two flexible laminated structures are laminated together to increase the thickness, the occurrence of breakage and damage may be avoided during the initial processing of the flexible laminated structure. After the initial processing is completed, the two flexible laminated structures may be separated by removing the release film, and the subsequent processing may be performed on the two flexible laminated structures to form two separated multilayer flexible circuit structures. Accordingly, the manufacturing methods of the multilayer flexible circuit structure provided by the invention are capable of improving the process yield rate and reducing the manufacturing cost. In addition, the manufacturing method of multilayer flexible circuit structure is also capable of bonding one or more inner build-up structures by requirements and forming the inner-layer circuits on the inner build-up structures before bonding the outer build-up structure. Accordingly, the manufacturing method of multilayer flexible circuit structure provided by the invention is capable of increasing more circuit layers by requirements by adopting simple technical solutions.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A manufacturing method of multilayer flexible circuit structure, comprising:
correspondingly bonding two first flexible substrates on two sides of a release film, and correspondingly forming two conductive materials on the two first flexible substrates, so as to form a double-side flexible laminated structure, wherein each of the first flexible substrates is disposed between the corresponding conductive material and the release film;
patterning the two conductive materials to form two first inner-layer circuits;
bonding two outer build-up structures on the two corresponding first flexible substrates, wherein each of the outer build-up structures comprises a bonding layer and a second flexible substrate, and the bonding layer is disposed between the second flexible substrate and the corresponding first inner-layer circuit;
removing the release film to separate the two first flexible substrates; and
forming an outer-layer circuit on each of the first flexible substrates and the corresponding outer build-up structure, wherein the outer-layer circuit is connected to the corresponding first inner-layer circuit, and each of the first flexible substrates, the corresponding first inner-layer circuit, the outer build-up structure and the outer-layer circuit correspondingly form a multilayer flexible circuit structure.

2. The manufacturing method of multilayer flexible circuit structure according to claim 1, further comprising:
before the step of patterning the two conductive materials to form the two first inner-layer circuits, forming at least one alignment target hole on a periphery of the double-side flexible laminated structure, wherein the alignment target hole penetrates the double-side flexible laminated structure; and the step of patterning the two conductive materials to form the two first inner-layer circuits comprises using the alignment target hole for alignment to form the two first inner-layer circuits.

3. The manufacturing method of multilayer flexible circuit structure according to claim 1, wherein the step of patterning the two conductive materials to form the two first inner-layer circuits comprises a photolithography process.

4. The manufacturing method of multilayer flexible circuit structure according to claim 1, further comprising:
before the step of removing the release film, removing a part of the periphery of the double-side flexible laminated structure.

5. The manufacturing method of multilayer flexible circuit structure according to claim 1, wherein the step of forming the outer-layer circuit on each of the first flexible substrates and the corresponding outer build-up structure further comprises:
respectively forming at least one blind hole on each of the first flexible substrates and the corresponding outer build-up structure, and forming at least one through hole on each of the first flexible substrates and the corresponding outer build-up structure;
forming a conductive layer on each of the first flexible substrates and the corresponding outer build-up structure, wherein each of the conductive layers is connected to the corresponding first inner-layer circuit through the corresponding blind holes and the through hole; and
patterning each of the conductive layers to form the outer-layer circuit on the corresponding first flexible substrate and the outer build-up structure.

6. The manufacturing method of multilayer flexible circuit structure according to claim 1, further comprising:
before the step of bonding the two outer build-up structures on the two corresponding first flexible substrates, bonding two inner build-up structures on the two corresponding first flexible substrates, wherein each of the inner build-up structures comprises a bonding layer and a third flexible substrate, and the bonding layer is disposed between the third flexible substrate and the corresponding first inner-layer circuit.

7. The manufacturing method of multilayer flexible circuit structure according to claim 6, further comprising:
after the step of bonding the two inner build-up structures on the two corresponding first flexible substrates, forming at least one blind hole on each of the inner build-up structures, and forming a second inner-layer circuit on each of the inner build-up structures, wherein each of the second inner-layer circuits is connected to the first inner-layer circuit through the corresponding blind hole.

8. The manufacturing method of multilayer flexible circuit structure according to claim 1, wherein each of the first flexible substrates and the corresponding conductive material comprise a flexible copper clad laminate (FCCL), and a material of each of the conductive materials comprises a copper foil.

9. The manufacturing method of multilayer flexible circuit structure according to claim 1, wherein materials of each of the first flexible substrates and each of the second flexible substrates comprise a thermosetting polyimide, and a plurality of ceramic powders are uniformly distributed in each of the first flexible substrates and each of the second flexible substrates.

10. The manufacturing method of multilayer flexible circuit structure according to claim 9, further comprising:
before forming each of the conductive materials, micro-etching an outer surface of each of the first flexible substrates to form a hyperactivity surface having a plurality of micro holes being uniformly distributed, and soaking each of the first flexible substrates in a solution having conductive ions to form a conductive film on the outer surface.

11. A manufacturing method of multilayer flexible circuit structure, comprising:
correspondingly bonding two flexible laminated structures on two sides of a release film to form a double-side flexible laminated structure, wherein each of the flexible laminated structures comprises a first flexible substrate and a first conductive material and a second conductive material disposed in two opposite surfaces of the first flexible substrate, and each of the second conductive materials is disposed between the corresponding first flexible substrate and the release film;
patterning the two first conductive materials to form two first inner-layer circuits;
bonding two outer build-up structures on the two corresponding flexible laminated structures, wherein each of the outer build-up structures comprises a bonding layer and a second flexible substrate, and the bonding layer is disposed between the second flexible substrate and the corresponding first inner-layer circuit;
removing the release film to separate the two flexible laminated structures; and
forming an outer-layer circuit on each of the flexible laminated structures and the corresponding outer build-up structure, wherein the outer-layer circuit is connected to the corresponding first inner-layer circuit, and each of the flexible laminated structures, the corresponding first inner-layer circuit, the outer build-up structure and the outer-layer circuit correspondingly form a multilayer flexible circuit structure.

12. The manufacturing method of multilayer flexible circuit structure according to claim 11, further comprising:
before the step of patterning the two first conductive materials to form the two first inner-layer circuits, forming at least one alignment target hole on a periphery of the double-side flexible laminated structure, wherein the alignment target hole penetrates the double-side flexible laminated structure; and the step of patterning the two first conductive materials to form the two first inner-layer circuits comprises using the alignment target hole for alignment to form the two first inner-layer circuits.

13. The manufacturing method of multilayer flexible circuit structure according to claim 11, wherein the step of bonding the two outer build-up structures on the two corresponding flexible laminated structures further comprises:
forming two third conductive materials on the two corresponding second flexible substrates, wherein each of the second flexible substrates is disposed between the corresponding third conductive material and the bonding layer.

14. The manufacturing method of multilayer flexible circuit structure according to claim 11, further comprising:
before the step of removing the release film, removing a part of the periphery of the double-side flexible laminated structure.

15. The manufacturing method of multilayer flexible circuit structure according to claim 11, wherein the step of forming the outer-layer circuit on each of the flexible laminated structures and the corresponding outer build-up structure further comprises:
respectively forming at least one blind hole on each of the flexible laminated structures and the corresponding outer build-up structure, and forming at least one through hole on each of the flexible laminated structures and the corresponding outer build-up structure;
forming a conductive layer on each of the flexible laminated structures and the corresponding outer build-up structure, wherein each of the conductive layers is connected to the corresponding first inner-layer circuit through the corresponding blind holes and the through hole; and
patterning the conductive layer to form the outer-layer circuit.

16. The manufacturing method of multilayer flexible circuit structure according to claim 11, further comprising:
before the step of bonding the two outer build-up structures on the two corresponding flexible laminated structures, bonding two inner build-up structures on the two corresponding flexible laminated structures, wherein each of the inner build-up structures comprises a bonding layer and a third flexible substrate, and the bonding layer is disposed between the third flexible substrate and the corresponding first inner-layer circuit.

17. The manufacturing method of multilayer flexible circuit structure according to claim 16, further comprising:
after the step of bonding the two inner build-up structures on the two corresponding flexible laminated structures, forming at least one blind hole on each of the inner build-up structures, and forming a second inner-layer circuit on each of the inner build-up structures, wherein each of the second inner-layer circuits is connected to the first inner-layer circuit through the corresponding blind hole.

18. The manufacturing method of multilayer flexible circuit structure according to claim 11, wherein each of the flexible laminated structures comprises a flexible copper clad laminate, and materials of each of the first conductive materials and each of the second conductive materials comprise a copper foil.

19. The manufacturing method of multilayer flexible circuit structure according to claim 11, wherein materials of each of the first flexible substrates and each of the second flexible substrates comprise a thermosetting polyimide, and a plurality of ceramic powders are uniformly distributed in each of the first flexible substrates and each of the second flexible substrates.

20. The manufacturing method of multilayer flexible circuit structure according to claim 19, further comprising:
before forming each of the first conductive materials and each of the second conductive materials, micro-etching the two opposite surfaces of each of the first flexible substrates to form two hyperactivity surfaces having a plurality of micro holes being uniformly distributed, and soaking each of the first flexible substrates in a solution having conductive ions to correspondingly form two conductive films on the two surfaces.
